(19) United States
(12) Patent Application Publication
(10) Pub. No.: US 2022/0271113 A1
(43) Pub. Date: Aug. 25, 2022

(54) DISPLAY PANEL AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Yang ZHOU, Beijing (CN); Yao HUANG, Beijing (CN); Yiyang ZHANG, Beijing (CN); Hao ZHANG, Beijing (CN); Linhong HAN, Beijing (CN)

(21) Appl. No.: 17/628,702

(22) PCT Filed: Mar. 25, 2020
(86) PCT No.: PCT/CN2020/081234

§ 371 Date: Jan. 20, 2022

(51) Int. Cl. H01L 27/32

(52) U.S. Cl. CPC H01L 27/3276

(57) ABSTRACT

A display panel and a display device are provided. The display panel includes: a light transmission region; a display region; a bezel region located between the light transmission region and the display region; a plurality of data lines including a plurality of bezel region data lines and a plurality of display region data lines, and a plurality of gate lines including a plurality of bezel region gate lines and a plurality of display region gate lines, each bezel region gate line includes a first portion, each bezel region data line includes a first portion, an extending direction of the first portion of the bezel region gale line is same as that of the first portion of the bezel region data line, and the first portion of the bezel region gate line overlaps with the first portion of one bezel region data line in a direction perpendicular to the base substrate.

### TECHNICAL FIELD

Embodiments of the present disclosure relate to a display panel and a display device.

### BACKGROUND

With the increasing requirements of users on the screen-to-body ratio of electronic apparatus products, flexible panels have been developed in various forms such as forming a groove or forming a hole. Before the technology of under-screen camera in the normal display region is matured, the more mature technology with the highest screen-to-body ratio at present is the technology of forming a hole within the screen.

### SUMMARY

Embodiments of the present disclosure provide a display panel and a display device.

At least one embodiment of the present disclosure provides a display panel, including: a light transmission region; a display region, arranged around the light transmission region or at a side of the light transmission region; a bezel region, located between the light transmission region and the display region; a plurality of data lines, located on a base substrate, including a plurality of bezel region data lines located in the bezel region and a plurality of display region data lines located in the display region, and the plurality of bezel region data lines being connected with the plurality of display region data lines, respectively; and a plurality of gate lines located on the base substrate, including a plurality of bezel region gate lines located in the bezel region and a plurality of display region gate lines located in the display region, and the plurality of bezel region gate lines being connected with the plurality of display region gate lines, respectively, each of the plurality of bezel region gate lines includes a first portion, each of the plurality of bezel region data lines includes a first portion, an extending direction of the first portion of the bezel region gate line is same as an extending direction of the first portion of the bezel region data line, and the first portion of the bezel region gate line overlaps with the first portion of one of the plurality of bezel region data lines in a direction perpendicular to the base substrate.

In one or more embodiments of the present disclosure, a width of a part of the bezel region gate line overlapping with the bezel region data line is less than or equal to a width of the bezel region data line.

In one or more embodiments of the present disclosure, a length of a part of the bezel region gate line overlapping with the bezel region data line along an extending direction of the part of the bezel region gate line is less than a length of the first portion of the bezel region gate line.

In one or more embodiments of the present disclosure, a length of a part of the bezel region gate line overlapping with the bezel region data line along an extending direction of the part of the bezel region gate line is greater than a width of the bezel region data line.

In one or more embodiments of the present disclosure, the first portion of the bezel region gate line includes a curved portion, and the first portion of the bezel region data line includes a curved portion.

In one or more embodiments of the present disclosure, both the curved portion of the bezel region gate line and the curved portion of the bezel region data line have an arc shape.

In one or more embodiments of the present disclosure, along a direction pointing from a position away from the light transmission region to a position close to the light transmission region, a length of a part of the bezel region gate line overlapping with the bezel region data line gradually increases.

In one or more embodiments of the present disclosure, the bezel region data lines that are adjacent to each other are located in different layers.

In one or more embodiments of the present disclosure, the bezel region data lines that are adjacent to each other include a first bezel region data line and a second bezel region data line, the first bezel region data line is closer to the base substrate than the second bezel region data line, and a first insulation layer is arranged between the first bezel region data line and the second bezel region data line.

In one or more embodiments of the present disclosure, the first bezel region data line and the display region data line connected to the first bezel region data line are integrated, and the second bezel region data line and the display region data line connected to the second bezel region data line are connected through a via hole penetrating the first insulation layer.

In one or more embodiments of the present disclosure, the first insulation layer includes a passivation layer and a first planarization layer.

In one or more embodiments of the present disclosure, the display panel further includes an initialization signal line and a first conductive line, the initialization signal line is located at a side of the plurality of gate lines away from the base substrate, the first conductive line is located in a same layer as the second bezel region data line, and the first conductive line is connected with the initialization signal line.

In one or more embodiments of the present disclosure, the first conductive line is arranged around the light transmission region.

In one or more embodiments of the present disclosure, a connection position of the second bezel region data line and the display region data line connected to the second bezel region data line is located at an inner side of the first conductive line.

In one or more embodiments of the present disclosure, the display panel further includes a second conductive line, the second conductive line is located in a same layer as the second bezel region data line, the second conductive line is arranged around the first conductive line, and the second conductive line and the first conductive line are insulated from each other.

In one or more embodiments of the present disclosure, the second conductive line has an opening at the light transmission region.

In one or more embodiments of the present disclosure, the display panel further includes a plurality of light emitting control signal lines, the plurality of light emitting control signal lines include a plurality of bezel region light emitting control signal lines located in the bezel region and a plurality of display region light emitting control signal lines located in the display region, the plurality of bezel region light emitting control signal lines are connected with the plurality of display region light emitting control signal lines, respectively, each of the plurality of bezel region light emitting control signal lines includes a first portion, an extending direction of the first portion of the bezel region light emitting control signal line is same as the extending direction of the first portion of the bezel region data line, and the first portion of the bezel region light emitting control signal line overlaps with the first portion of one of the plurality of bezel region data lines in the direction perpendicular to the base substrate.

In one or more embodiments of the present disclosure, one of the bezel region gate line and the bezel region light emitting control signal line overlaps with the first bezel region data line, and the other of the bezel region gate line and the bezel region light emitting control signal line overlaps with the second bezel region data line.

In one or more embodiments of the present disclosure, the bezel region gate line overlaps with the first bezel region data line, the bezel region light emitting control signal line overlaps with the second bezel region data line, and a thickness of an insulation layer between the bezel region gate line and the first bezel region data line is less than a thickness of an insulation layer between the bezel region light emitting control signal line and the second bezel region data line.

In one or more embodiments of the present disclosure, a count of the plurality of light emitting control signal lines is equal to a count of the plurality of gate lines.

In one or more embodiments of the present disclosure, the bezel region light emitting control signal line and the display region light emitting control signal line are located in different layers.

In one or more embodiments of the present disclosure, the bezel region gate line is closer to the base substrate than the bezel region light emitting control signal line, and a gate insulation layer is arranged between the bezel region gate line and the bezel region light emitting control signal line.

In one or more embodiments of the present disclosure, an interlayer insulation layer is arranged between the plurality of light emitting control signal lines and the plurality of first bezel region data lines.

In one or more embodiments of the present disclosure, the display panel further includes a second planarization layer, the second planarization layer covers the plurality of second bezel region data lines.

In one or more embodiments of the present disclosure, a material of at least one selected from the group consisting of the first bezel region data line, the second bezel region data line, the gate line, and the light emitting control signal line includes metal or alloy.

In one or more embodiments of the present disclosure, the display panel further includes a display unit, the display unit includes an organic light emitting diode.

In one or more embodiments of the present disclosure, the display panel further includes an isolation pillar, the isolation pillar is located in the bezel region and arranged around the light transmission region, the isolation pillar is located at a side of the plurality of bezel region data lines close to the light transmission region, and the isolation pillar forms an inner boundary of the bezel region.

In one or more embodiments of the present disclosure, the isolation pillar is made of a metal material.

In one or more embodiments of the present disclosure, the isolation pillar is arranged in a same layer as the first bezel region data line or the second bezel region data line.

In one or more embodiments of the present disclosure, the isolation pillar includes a first sub-layer, a second sub-layer and a third sub-layer, the first sub-layer is closer to the base substrate than the second sub-layer, the second sub-layer is closer to the base substrate than the third sub-layer, a size of the second sub-layer along a radial direction of the light transmission region is less than a size of the first sub-layer along the radial direction of the light transmission region, and the size of the second sub-layer along the radial direction of the light transmission region is less than a size of the third sub-layer along the radial direction of the light transmission region.

In one or more embodiments of the present disclosure, the organic light emitting diode includes a light emitting functional layer, the light emitting functional layer includes a first portion located at a side of the isolation pillar away from the light transmission region and a second portion located on the isolation pillar, and the first portion of the light emitting functional layer and the second portion of the light emitting functional layer are broken at a side edge of the isolation pillar.

In one or more embodiments of the present disclosure, the light transmission region includes a first light transmission region and a second light transmission region, each of the plurality of bezel region gate lines includes a second portion, the second portion of the bezel region gate line is located between the first light transmission region and the second light transmission region, the second portion of the bezel region gate line is connected with a first electrode plate of a load capacitor, and a second electrode plate of the load capacitor is opposite to the first electrode plate of the load capacitor.

In one or more embodiments of the present disclosure, the second electrode plate of the load capacitor partially overlaps with the second portion of the bezel region gate line.

In one or more embodiments of the present disclosure, the second portion of the bezel region gate line and the first electrode plate of the load capacitor are integrated.

In one or more embodiments of the present disclosure, the display panel further includes a first power line, the first power line is configured to provide a constant voltage signal, and the second electrode plate of the load capacitor is connected with the first power line.

At least one embodiment of the present disclosure provides a display device, including any one of the display panels as described above.

### BRIEF DESCRIPTION OF THE DRAWINGS

In order to clearly illustrate the technical solution of the embodiments of the present disclosure, the drawings of the embodiments will be briefly described in the following. It is obvious that the described drawings are only related to some embodiments of the present disclosure and thus are not construed any limitation to the present disclosure.

FIG. 1 is a schematic diagram of a display panel;

FIG. 2 is a schematic diagram of a display panel;

FIG. 3 is a schematic diagram of a display panel;

FIG. 4 is a schematic diagram of a display panel;

FIG. 5 is a partial view of a display panel;

FIG. 6 is a schematic diagram of signal lines providing signals for each pixel unit in a display panel provided by an embodiment of the present disclosure;

FIG. 7 is a partial plan view of a display panel provided by an embodiment of the present disclosure;

FIG. 8 is a plan view of a data line in FIG. 7;

FIG. 9 is a plan view of a gate line and a light emitting control signal line in FIG. 7;

FIG. 10 is a cross-sectional view taken along line A-B in FIG. 7;

FIG. 11 is a cross-sectional view of a display panel provided by an embodiment of the present disclosure;

FIG. 12 is a plan view of a display panel provided by an embodiment of the present disclosure;

FIG. 13 is a plan view of a third conductive pattern layer and a fourth conductive pattern layer in a display panel provided by an embodiment of the present disclosure;

FIG. 14 is a plan view of a fourth conductive pattern layer in a display panel provided by an embodiment of the present disclosure;

FIG. 15 is a cross-sectional view of a display panel provided by an embodiment of the present disclosure;

FIG. 16 is a plan view of an initialization signal line and a second conductive line in a display panel provided by an embodiment of the present disclosure;

FIG. 17 is a cross-sectional view of a display panel provided by an embodiment of the present disclosure;

FIG. 18 is a cross-sectional view of a display panel provided by an embodiment of the present disclosure;

FIG. 19 is a partial view of a display panel provided by an embodiment of the present disclosure;

FIG. 20 is a partial view of a display panel provided by an embodiment of the present disclosure;

FIG. 21 is a partial view of a display panel provided by an embodiment of the present disclosure;

FIG. 22 is a schematic diagram of a display panel provided by an embodiment of the present disclosure;

FIG. 23 is a schematic diagram of a display panel provided by an embodiment of the present disclosure;

FIG. 24 is a partial view of FIG. 23;

FIG. 25 is a plan view of a dummy pixel unit at a second portion of a bezel region gate line;

FIG. 26 is a pattern of an active layer of the dummy pixel unit in FIG. 25;

FIG. 27 is a pattern of a first conductive pattern layer of the dummy pixel unit in FIG. 25;

FIG. 28 is a pattern of a second conductive pattern layer of the dummy pixel unit in FIG. 25;

FIG. 29 is a pattern of an insulation layer of the dummy pixel unit in FIG. 25;

FIG. 30 is a pattern of a third conductive pattern layer of the dummy pixel unit in FIG. 25;

FIG. 31 is a schematic diagram of a pixel circuit structure of a display panel provided by an embodiment of the present disclosure;

FIG. 32 is a timing signal diagram of a pixel unit in a display panel provided by an embodiment of the present disclosure; and

FIG. 33 is a plan view of a display substrate provided by an embodiment of the present disclosure.

### DETAILED DESCRIPTION

For more clear understanding of the objectives, technical details and advantages of the embodiments of the present disclosure, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount or importance, but distinguish various components. Also, the terms “comprise”, “comprising”, “include”, “including”, etc., are intended to specify that the elements or the objects stated before these terms encompass the elements or the objects and equivalents thereof listed after these terms, but do not preclude the other elements or objects. The phrases “connect”, “connected” and the like are not limited to a physical or mechanical connection, but also include an electrical connection, either directly or indirectly. “On,” “under,” “right,” “left” and the like are only used to indicate relative position relationship, and when the position of the described object is changed, the relative position relationship may be changed accordingly.

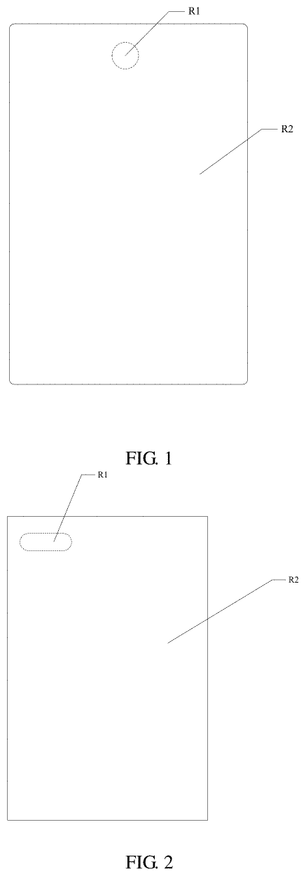

FIG. 1 is a schematic diagram of a display panel. As illustrated in FIG. 1, the display panel includes a light transmission region R1 and a display region R2. In the case where the scheme of forming a hole within the screen is adopted, at least part of the structure in the light transmission region R1 is removed, that is, the scheme of forming a hole within the screen needs to sacrifice part of the display region to form the light transmission region. As illustrated in FIG. 1, the light transmission region R1 is circular. The light transmission region R1 is a region where a hole is formed. The size of the region where a hole is formed determines the number of display pixel units missing from the current display pixel unit row. The more the number of the missing display pixel units, the more the missing load of the gate line (scan signal), and the more capacitance needed to be compensated for the scan signal.

FIG. 2 is a schematic diagram of a display panel. The shape of the light transmission region R1 of the display panel illustrated in FIG. 2 is different from that of the light transmission region R1 of the display panel illustrated in FIG. 1. As illustrated in FIG. 2, the light transmission region R1 has a racetrack shape. The shape of the light transmission region R1 of the display panel provided by the embodiment of the present disclosure is not limited to the shapes illustrated in FIG. 1 and FIG. 2, and can be arranged as needed. The arrangement position of the light transmission region R1 of the display panel provided by the embodiments of the present disclosure is not limited to those illustrated in the figures, and can be arranged as needed. The following embodiments of the present disclosure are described with reference to the case where the shape of the light transmission region R1 is circular.

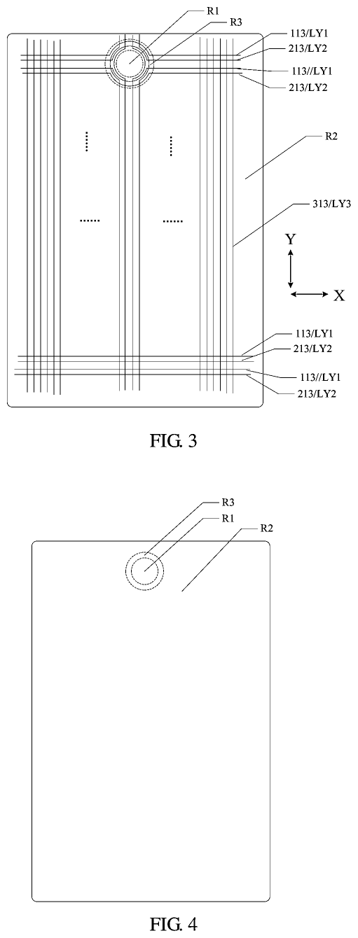

FIG. 3 is a schematic diagram of a display panel. As illustrated in FIG. 3, a hole needs to be formed in the light transmission region R1, the trace lines that should have been arranged in this region in the case where a hole is not formed need to extend along the edge of the light transmission region R1 in the case where a hole is formed, thus forming a bezel region R3. As illustrated in FIG. 3, the bezel region R3 is located between the display region R2 and the light transmission region RE The display region R2 surrounds the light transmission region R1, and the bezel region R3 surrounds the light transmission region RE Of course, in some other embodiments, the display region R2 can be located at a side of the light transmission region R1, and the bezel region R3 can be located between the display region R2 and the light transmission region RE FIG. 3 illustrates data lines 313, gate lines 113 and light emitting control signal lines 213.

As illustrated in FIG. 3, the gate line 113 is located in a first conductive pattern layer LY1, the light emitting control signal line 213 is located in a second conductive pattern layer LY2, and the data line 313 is located in a third conductive pattern layer LY3. Of course, in some other embodiments, the light emitting control signal line 213 can also be located in the first conductive pattern layer LY1.

FIG. 3 illustrates a first direction X and a second direction Y. As illustrated in FIG. 3, the data line 313 extends along the second direction Y, and both the gate line 113 and the light emitting control signal line 213 extend along the first direction X. The extending direction of each signal line described here refers to an overall extending trend of the signal line, and it is not excluded that the signal line includes parts that do not extend along this direction.

All signal lines are not illustrated in FIG. 3, and the display panel provided by the embodiments of the present disclosure can further include other signal lines. For example, the display panel provided by the embodiments of the present disclosure can further include signal lines such as a power line and an initialization signal line, etc.

FIG. 4 is a schematic diagram of a display panel. FIG. 4 illustrates a light transmission region R1, a display region R2 and a bezel region R3. And for the sake of clarity, the signal lines are omitted.

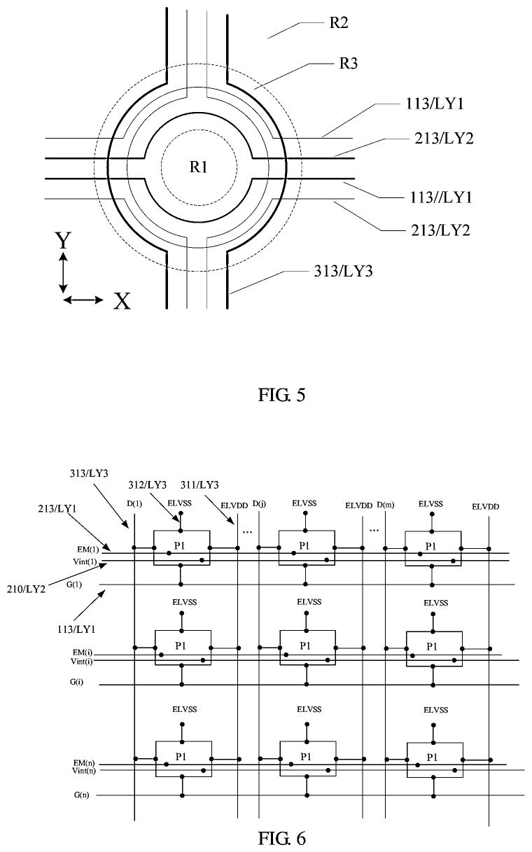

FIG. 5 is a partial view of a display panel. FIG. 5 is a schematic diagram of a light transmission region R1 and the structure in the vicinity thereof. FIG. 5 illustrates four data lines 313, two gate lines 113, and two light emitting control signal lines 213.

On the one hand, forming a hole within the screen not only causes missing of the pixel circuits, but also causes missing of loading in the lateral and vertical direction in the region where a hole is formed (light transmission region R1). However, the missing load is not compensated in the common design. According to the design experience of the irregular screen that is grooved, the missing load may lead to display difference at the boundary of the missing pixel units, such as a display defect that the lateral range where the hole is located is dark. At present, in the hole-forming design of the panel appearing in the market, due to the small hole size, the display difference problem of a conventional display image may not be exposed, but the display defect will occur under a more strict display condition (e.g., high refresh rate). For another example, the whole product manufacturer needs more camera sensors to be disposed in the front, and needs to design a racetrack-shape hole at the same row position, so that the missing load is more, and the display defect is more easily exposed.

On the other hand, a plurality of signal lines are formed in the bezel region, and the space occupied by the signal lines affects the size of the bezel region, which is not conducive to increasing the screen-to-body ratio.

FIG. 6 is a schematic diagram of signal lines providing signals for each pixel unit in a display panel provided by an embodiment of the present disclosure. Each display pixel unit P1 includes a light emitting unit and a pixel circuit structure that provides a driving current for the light emitting unit. The light emitting unit can be an electroluminescent unit, such as an organic electroluminescent unit, for example, an organic light emitting diode (OLED). The display pixel unit P1 is a pixel unit that emits light normally. The display pixel unit P1 is located in the display region R2.

FIG. 6 illustrates gate lines 113, data lines 313, first power lines 311, second power lines 312, light emitting control signal lines 213 and initialization signal lines 210. For example, the gate line 113 is configured to provide at least one of a scan signal SCAN or a reset signal RESET to the pixel circuit structure, and in the case where the gate line 113 is configured to provide a reset signal RESET to the pixel circuit structure, it can also be referred to as a reset control signal line. For example, in the display panel, the second reset control signal line 112 of the pixel units of a current row serves as the first reset control signal line 111 of the pixel units of a next row. The light emitting control signal line 213 is configured to provide a light emitting control signal EM to the display pixel unit P1. The data line 313 is configured to provide a data signal DATA to the pixel circuit structure 10, the first power line 311 is configured to provide a first voltage signal ELVDD that is constant to the pixel circuit structure 10, the second power line 312 is configured to provide a second voltage signal ELVSS that is constant to the pixel circuit structure 10, and the first voltage signal ELVDD is greater than the second voltage signal ELVSS. The initialization signal line 210 is configured to provide an initialization signal Vint to the pixel circuit structure. The initialization signal Vint is a constant voltage signal, and the magnitude thereof can be between the first voltage signal ELVDD and the second voltage signal ELVSS, but is not limited thereto. For example, the initialization signal Vint can be less than or equal to the second voltage signal ELVSS. For example, the pixel circuit structure outputs a driving current to drive the light emitting unit to emit light under the control of signals, such as the scan signal SCAN, the data signal DATA, the initialization signal Vint, the first voltage signal ELVDD, the second voltage signal ELVSS, the light emitting control signal EM, etc.

For example, as illustrated in FIG. 6, the gate line 113 is located in the first conductive pattern layer LY1, the initialization signal line 210 is located in the second conductive pattern layer LY2, the data line 313 and the first power line 311 are located in the third conductive pattern layer LY3, and the second power line 312 can also be located in the third conductive pattern layer LY3.

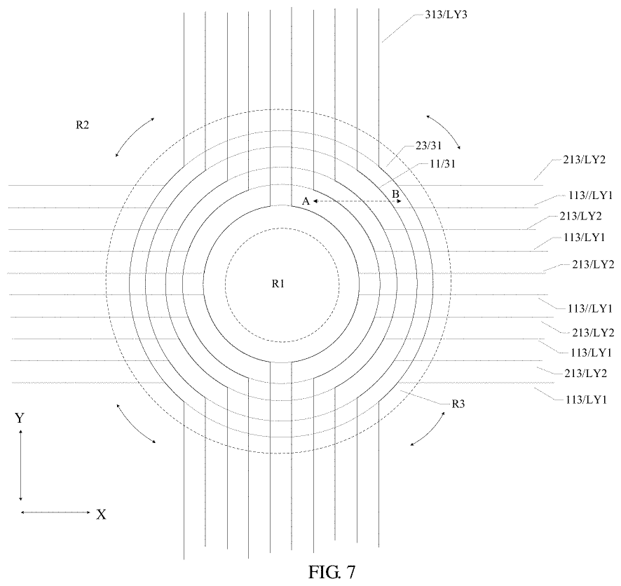

FIG. 7 is a partial plan view of a display panel provided by an embodiment of the present disclosure. As illustrated in FIG. 7, the display panel includes a light transmission region R1, a display region R2, a bezel region R3, a plurality of light emitting control signal lines 213, a plurality of data lines 313, and a plurality of gate lines 113.

As illustrated in FIG. 7, the display region R2 is arranged around the light transmission region R1 or at a side of the light transmission region RE The bezel region R3 is located between the light transmission region R1 and the display region R2.

For example, referring to FIG. 6 and FIG. 7, the number of the plurality of light emitting control signal lines 213 is equal to the number of the plurality of gate lines 113. That is, one light emitting control signal line 213 is provided for each row of pixel units, and the light emitting control signal is used for progressive driving, thereby alleviating the dimming flicker problem in low gray-scale. In this case, if the number of horizontal signal lines is equal to the number of vertical signal lines in the bezel region R3 and the light transmission region R1 is circular, the bezel region R3 can be annular, but is not limited thereto.

As illustrated in FIG. 7, in the bezel region R3, one gate line 113 overlaps with one data line 313 at a first position and overlaps with another data line 313 at a second position. As illustrated in FIG. 7, in the bezel region R3, one light emitting control signal line 213 overlaps with one data line 313 at a third position and overlaps with another data line 313 at a fourth position. As illustrated in FIG. 7, in the bezel region R3, one data line 313 overlaps with one light emitting control signal line 213 at a fifth position and overlaps with one gate line 113 at a sixth position.

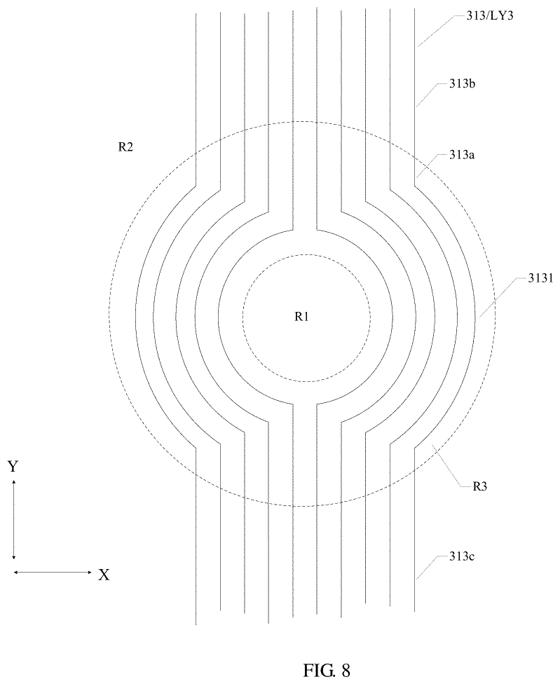

FIG. 8 is a plan view of the data line in FIG. 7. Referring to FIG. 7 and FIG. 8, the plurality of data lines 313 are located on the base substrate, and include a plurality of bezel region data lines 313a located in the bezel region R3 and a plurality of display region data lines 313b located in the display region R2, and the plurality of bezel region data lines 313a are connected with the plurality of display region data lines 313b, respectively. Each data line 313 includes a bezel region data line 313a located in the bezel region R3 and a display region data line 313b located in the display region R2. FIG. 8 further illustrates a plurality of display region data lines 313c, and the plurality of display region data lines 313c are connected with a plurality of bezel region data lines 313a, respectively. In this case, each data line 313 includes a bezel region data line 313a located in the bezel region R3, a display region data line 313b located in the display region R2 and a display region data line 313c located in the display region R2. The display region data line 313b and the display region data line 313c are disposed at both sides of the bezel region data line 313a, respectively.

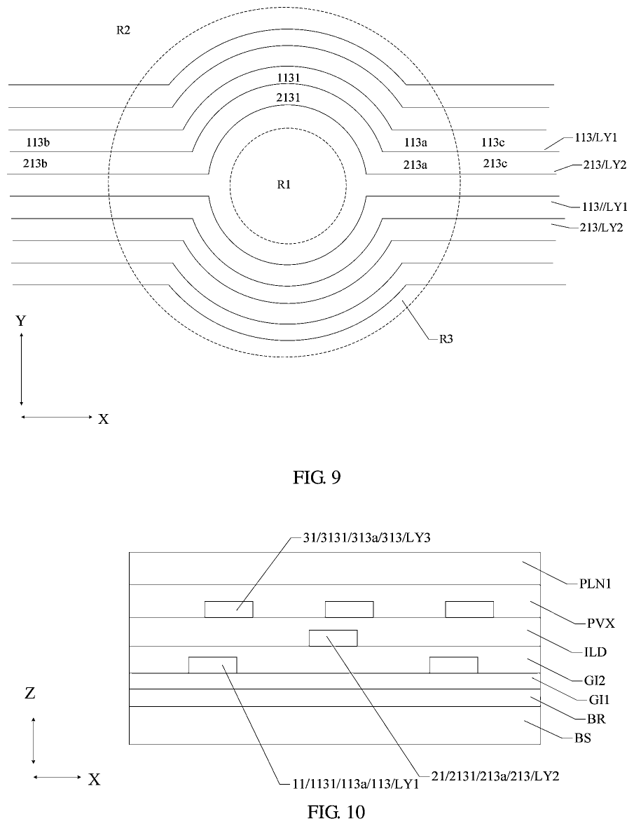

FIG. 9 is a plan view of the gate line and the light emitting control signal line in FIG. 7. Referring to FIG. 7 and FIG. 9, the plurality of gate lines 113 are located on the base substrate, and include a plurality of bezel region gate lines 113a located in the bezel region R3 and a plurality of display region gate lines 113b located in the display region R2, and the plurality of bezel region gate lines 113a are connected with the plurality of display region gate lines 113b, respectively. Each gate line 113 includes a bezel region gate line 113a located in the bezel region R3 and a display region gate line 113b located in the display region R2. FIG. 9 further illustrates a plurality of display region gate lines 113c, and the plurality of display region gate lines 113c are connected with a plurality of bezel region gate lines 113a, respectively. In this case, each gate line 113 includes a bezel region gate line 113a located in the bezel region R3, a display region gate line 113b located in the display region R2 and a display region gate line 113c located in the display region R2. The display region gate line 113b and the display region gate line 113c are disposed at both sides of the bezel region gate line 113a, respectively.

Referring to FIG. 7 to FIG. 9, the bezel region gate line 113a includes a first portion 1131, and the bezel region data line 313a includes a first portion 3131, the extending direction of the first portion 1131 of the bezel region gate line 113a is the same as the extending direction of the first portion 3131 of the bezel region data line 313a, and the first portion 1131 of the bezel region gate line 113a overlaps with the first portion 3131 of one of the plurality of bezel region data lines 313a in a direction perpendicular to the base substrate. For example, the same extending direction may refer to that two elements have conformal parts, and the conformal parts have the same extending direction, or the conformal parts have the same extending trend. For example, the same extending direction may refer to that two elements extend in the same direction at the same point. For example, the same extending direction may refer to a general extending trend of the line, and in the case where the line is not a straight line, the tangent direction of the line can be the extending direction thereof. The same extending direction includes the extending direction are completely the same and approximately the same. In FIG. 7, the extending directions of overlapping parts of different elements are illustratively described by curves with double-arrows.

FIG. 10 is a cross-sectional view taken along line A-B in FIG. 7. As illustrated in FIG. 10, the display substrate includes a base substrate BS. A barrier layer BR is provided on the base substrate BS, a first gate insulation layer GI1 is provided on the barrier layer BR, a first conductive pattern layer LY1 is provided on the first gate insulation layer GIL and the first conductive pattern layer LY1 includes the gate line 113. A second gate insulation layer GI2 is provided on the first conductive pattern layer LY1, a second conductive pattern layer LY2 is provided on the second gate insulation layer GI2, and the second conductive pattern layer LY2 includes the light emitting control signal line 213. An interlayer insulation layer ILD is provided on the second conductive pattern layer LY2. A third conductive pattern layer LY3 is provided on the interlayer insulation layer ILD, and the third conductive pattern layer LY3 includes the data line 313. A passivation layer PVX and a first planarization layer PLN1 are provided on the third conductive pattern layer LY3.

FIG. 10 illustrates a third direction Z. The third direction Z is perpendicular to the first direction X. The third direction Z is also perpendicular to the second direction Y. And the third direction Z is the direction perpendicular to the base substrate BS. Referring to FIG. 7 to FIG. 10, the first portion 1131 of the bezel region gate line 113a overlaps with the first portion 3131 of one of the plurality of bezel region data lines 313a in the direction perpendicular to the base substrate BS.

According to the previous test experience and simulation results, the load difference of gate lines has the greatest influence on the display panel, and the load affects the rising edge time and the falling edge time of the scan signal SCAN, thus affecting the writing time of the data signal DATA. The difference of writing time of the data signal DATA directly leads to the brightness difference of the display panel. Therefore, the gate line and the data line are overlapped to form two electrode plates of a capacitor, respectively, which compensates for the missing load of the gate line, reduces the brightness difference of the display panel and improves the display effect. In the display panel provided by the embodiments of the present disclosure, the panel display difference caused by hole-forming is corrected, and the display quality is improved.

For example, referring to FIG. 7 and FIG. 10, the part 11 of the bezel region gate line 113a overlapping with the bezel region data line 313a is a part of the first portion 1131 of the bezel region gate line 113a, and the width of the part 11 of the bezel region gate line 113a overlapping with the bezel region data line 313a is less than or equal to the width of the bezel region data line 313a.

For example, referring to FIG. 7 and FIG. 8, the part 31 of the bezel region data line 313a overlapping with the bezel region gate line 113a is a part of the first portion 3131 of the bezel region data line 313a. The length of the part 31 of the bezel region data line 313a overlapping with the bezel region gate line 113a along the extending direction of the part 31 of the bezel region data line 313a is less than the length of the first portion 3131 of the bezel region data line 313a.

In the embodiments of the present disclosure, the length of an element can refer to its size in the extending direction thereof, and the width of an element can refer to its size in a direction perpendicular to the extending direction thereof.

For example, referring to FIG. 7 and FIG. 9, the length of the part 11 of the bezel region gate line 113a overlapping with the bezel region data line 313a along the extending direction of the part 11 of the bezel region gate line 113a is less than the length of the first portion 1131 of the bezel region gate line 113a.

For example, referring to FIG. 7, the length of the part 11 of the bezel region gate line 113a overlapping with the bezel region data line 313a along the extending direction of the part 11 of the bezel region gate line 113a is greater than the width of the bezel region data line 313a.

For example, referring to FIG. 7 and FIG. 9, the first portion 1131 of the bezel region gate line 113a includes a curved portion, and the first portion 3131 of the bezel region data line 313a includes a curved portion. For example, the curved portion of the bezel region gate line 113a and the curved portion of the bezel region data line 313a both include an arc shape.

For example, referring to FIG. 7, along a direction pointing from a position away from the light transmission region R1 to a position close to the light transmission region R1, the length of the part of the bezel region gate line 113a overlapping with the bezel region data line 313a gradually increases.

For example, referring to FIG. 7, FIG. 9 and FIG. 10, the display panel further includes a plurality of light emitting control signal lines 213, the plurality of light emitting control signal lines 213 include a plurality of bezel region light emitting control signal lines 213a located in the bezel region R3 and a plurality of display region light emitting control signal lines 213b located in the display region R2, and the plurality of bezel region light emitting control signal lines 213a are connected with the plurality of display region light emitting control signal lines 213b, respectively. The bezel region light emitting control signal line 213a includes a first portion 2131, the extending direction of the first portion 2131 of the bezel region light emitting control signal line 213a is the same as the extending direction of the first portion 3131 of the bezel region data line 313a, and the first portion 2131 of the bezel region light emitting control signal line 213a overlaps with the first portion 3131 of one of the plurality of bezel region data lines 313a in the direction perpendicular to the base substrate BS. Therefore, the light emitting control signal line and the data line are overlapped to form two electrode plates of a capacitor, respectively, thus compensating the missing load of the light emitting control signal line and improving the display effect.

For example, as illustrated in FIG. 9, each light emitting control signal line 213 includes a bezel region light emitting control signal line 213a located in the bezel region R3 and a display region light emitting control signal line 213b located in the display region R2.

For example, as illustrated in FIG. 9, the plurality of light emitting control signal lines 213 further include a plurality of display region light emitting control signal lines 213c located in the display region R2, and the plurality of display region light emitting control signal lines 213c are connected with the plurality of bezel region light emitting control signal lines 213a, respectively. Each light emitting control signal line 213 includes a bezel region light emitting control signal line 213a located in the bezel region R3, a display region light emitting control signal line 213b located in the display region R2, and a display region light emitting control signal line 213c located in the display region R2. The display region light emitting control signal line 213b and the display region light emitting control signal line 213c are disposed at both sides of the bezel region light emitting control signal line 213a, respectively.

For example, referring to FIG. 7 and FIG. 9, the length of the part 21 of the bezel region light emitting control signal line 213a overlapping with the bezel region data line 313a along the extending direction of the part 21 of the bezel region light emitting control signal line 213a is less than the length of the first portion 1131 of the bezel region light emitting control signal line 213a.

For example, as illustrated in FIG. 7, the length of the part 21 of the bezel region light emitting control signal line 213a overlapping with the bezel region data line 313a along the extending direction of the part 21 of the bezel region light emitting control signal line 213a is greater than the width of the bezel region data line 313a.

For example, referring to FIG. 7 and FIG. 9, the first portion 2131 of the bezel region light emitting control signal line 213a includes a curved portion. For example, the curved portion of the bezel region light emitting control signal line 213a and the curved portion of the bezel region data line 313a both include an arc shape.

For example, as illustrated in FIG. 7, along the direction pointing from a position away from the light transmission region R1 to a position close to the light transmission region R1, the length of the part of the bezel region light emitting control signal line 213a overlapping with the bezel region data line 313a gradually increases.

For example, as illustrated in FIG. 7, a plurality of portions 21 of the bezel region light emitting control signal lines 213a overlapping with the bezel region data lines 313a are alternately arranged with a plurality of portions 11 of the bezel region gate lines 113a overlapping with the bezel region data lines 313a. That is, the plurality of portions 21 and the plurality of portions 11 are alternately arranged.

FIG. 7 is illustrated by taking that the first portion 1131 of the bezel region gate line 113a is a part of a circle, the first portion 3131 of the bezel region data line 313a is a part of a circle and the first portion 2131 of the bezel region light emitting control signal line 213a is a part of a circle as an example, which is not limited to this case. In some other embodiments, the first portion 1131 of the bezel region gate line 113a can also adopt other curved forms, the first portion 3131 of the bezel region data line 313a can also adopt other curved forms, and the first portion 2131 of the bezel region light emitting control signal line 213a can also adopt other curved forms.

FIG. 7 and FIG. 10 are illustrated by taking that adjacent data lines 313 are located in the same layer, that is, the data lines 313 that are adjacent to each other are located in the third conductive pattern layer LY3, as an example, but are not limited thereto. For example, in some other embodiments, the bezel region data lines 313a that are adjacent to each other and illustrated in FIG. 7 and FIG. 10 can also be located in different layers.

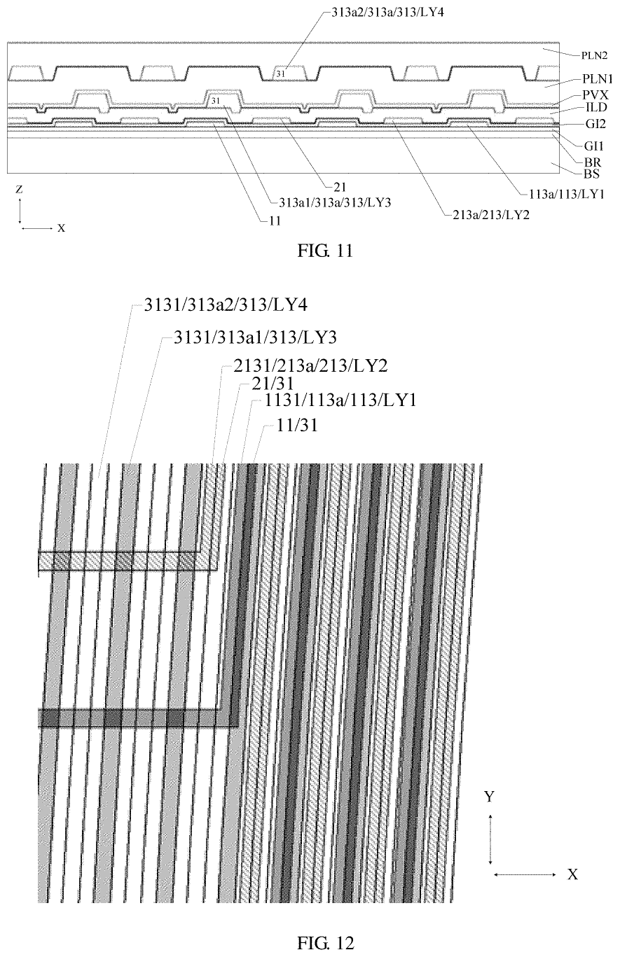

FIG. 11 is a cross-sectional view of a display panel provided by an embodiment of the present disclosure. As illustrated in FIG. 11, the bezel region data lines 313a that are adjacent to each other are located in different layers, thereby reducing the space occupied by the signal lines in the bezel region at the periphery of the light transmission region, and realizing a narrow bezel and a higher screen-to-body ratio. For example, as illustrated in FIG. 11, the bezel region data lines 313a that are adjacent to each other include a first bezel region data line 313a1 and a second bezel region data line 313a2, the first bezel region data line 313a1 is closer to the base substrate BS than the second bezel region data line 313a2, and an insulation layer is disposed between the first bezel region data line 313a1 and the second bezel region data line 313a2. For example, the insulation layer includes a passivation layer PVX and a first planarization layer PLN1.

For example, in the embodiments of the present disclosure, the light emitting control signal line 213 can be located in the second conductive pattern layer LY2, but is not limited thereto. In some other embodiments, the light emitting control signal line 213 can be formed in segments; for example, the bezel region light emitting control signal line 213a is located in the second conductive pattern layer LY2, while a part of the light emitting control signal line 213 other than the bezel region light emitting control signal line 213a is located in the first conductive pattern layer LY1. For example, as illustrated in FIG. 9, the display region light emitting control signal line 213b is located in the first conductive pattern layer LY1, while the bezel region light emitting control signal line 213a is located in the second conductive pattern layer LY2. For example, only the part of the light emitting control signal lines 213 in the vicinity of the light transmission region R1 are formed in segments, and the light emitting control signal lines 213 at other positions can all be located in the first conductive pattern layer LY1. For example, segments of the light emitting control signal line 213 located in different layers are connected through via holes penetrating the insulation layer therebetween.

FIG. 12 is a plan view of a display panel provided by an embodiment of the present disclosure. FIG. 12 illustrates a first bezel region data line 313a1, a second bezel region data line 313a2, a bezel region light emitting control signal line 213a, and a bezel region gate line 113a.

Referring to FIG. 11 and FIG. 12, the first portion 3131 of the first bezel region data line 313a1 overlaps with the first portion 1131 of the bezel region gate line 113a in the direction perpendicular to the base substrate BS. Because the sum of the thicknesses of the second gate insulation layer GI2 and the interlayer insulation layer ILD between the first portion 3131 of the first bezel region data line 313a1 and the first portion 1131 of the bezel region gate line 113a is relatively small, the capacitance between the bezel region gate line and the bezel region data line is greatly improved, the missing load of the bezel region gate line is reduced, the load of the bezel region gate line is increased, and the display effect is improved. Generally speaking, the influence of the missing load of the gate line on the display effect is greater than the influence of the missing load of the light emitting control signal line on the display effect.

Referring to FIG. 11 and FIG. 12, the first portion 3131 of the second bezel region data line 313a2 overlaps with the first portion 2131 of the bezel region light emitting control signal line 213a in the direction perpendicular to the base substrate BS. Therefore, the missing load of the bezel region light emitting control signal line is reduced, the load of the bezel region light emitting control signal line is increased, the display effect is improved, the space occupied by the signal lines in the bezel region at the periphery of the light transmission region is reduced, and a narrow bezel and a higher screen-to-body ratio are realized. For example, as illustrated in FIG. 11, the thickness of the first planarization layer PLN1 is greater than the sum of the thicknesses of the second gate insulation layer GI2 and the interlayer insulation layer ILD.

Referring to FIG. 11 and FIG. 12, the first bezel region data line 313a1 is located in the third conductive pattern layer LY3, and the second bezel region data line 313a2 is located in the fourth conductive pattern layer LY4. An insulation layer is disposed between the third conductive pattern layer LY3 and the fourth conductive pattern layer LY4, and the insulation layer includes a passivation layer PVX and a first planarization layer PLN1. The bezel region gate line 113a is located in the first conductive pattern layer LY1, the bezel region light emitting control signal line 213a is located in the second conductive pattern layer LY2, and a second gate insulation layer GI2 is disposed between the first conductive pattern layer LY1 and the second conductive pattern layer LY2. An interlayer insulation layer ILD is disposed between the second conductive pattern layer LY2 and the third conductive pattern layer LY3. A barrier layer BR and a first gate insulation layer GI1 are disposed between the base substrate BS and the first conductive pattern layer LY1. The first gate insulation layer GI1 is closer to the base substrate BS than the barrier layer BR is. A second planarization layer PLN2 is disposed at a side of the fourth conductive pattern layer LY4 away from the base substrate BS. In the embodiments of the present disclosure, a plurality of elements being located in the same layer refers to that the plurality of elements are formed by the same film layer using the same patterning process. For example, elements located in the first conductive pattern layer LY1 are formed by the same film layer using the same patterning process, elements located in the second conductive pattern layer LY2 are formed by the same film layer using the same patterning process, elements located in the third conductive pattern layer LY3 are formed by the same film layer using the same patterning process, and elements located in the fourth conductive pattern layer LY4 are formed by the same film layer using the same patterning process.

FIG. 11 and FIG. 12 also illustrate the part 11 of the bezel region gate line 113a overlapping with the bezel region data line 313a, the part 21 of the bezel region light emitting control signal line 213a overlapping with the bezel region data line 313a, the part 31 of the bezel region data line 313a overlapping with the bezel region gate line 113a, and the part 31 of the bezel region data line 313a overlapping with the bezel region light emitting control signal line 213a.

In FIG. 11 and FIG. 12, the first portion 3131 of the first bezel region data line 313a1 partially overlaps with the first portion 1131 of the bezel region gate line 113a in the direction perpendicular to the base substrate BS. However, in some other embodiments, in order to obtain more overlapping areas and increase the value of compensation capacitance, the orthographic projection of the first portion 3131 of the first bezel region data line 313a1 on the base substrate BS completely covers the orthographic projection of the first portion 1131 of the bezel region gate line 113a on the base substrate BS. For example, in some embodiments, the orthographic projection of the first portion 3131 of the bezel region data line 313a on the base substrate BS completely covers the orthographic projection of the first portion 1131 of the bezel region gate line 113a on the base substrate BS. The data line covering the first portion 1131 of the bezel region gate line 113a can be disposed in a predetermined layer as needed.

In FIG. 11 and FIG. 12, the first portion 3131 of the second bezel region data line 313a2 partially overlaps with the first portion 2131 of the bezel region light emitting control signal line 213a in the direction perpendicular to the base substrate BS. However, in some other embodiments, in order to obtain more overlapping areas and increase the value of compensation capacitance, the orthographic projection of the first portion 3131 of the second bezel region data line 313a2 on the base substrate BS covers the orthographic projection of the first portion 2131 of the bezel region light emitting control signal line 213a on the base substrate BS. For example, in some embodiments, the orthographic projection of the first portion 3131 of the bezel region data line 313a on the base substrate BS covers the orthographic projection of the first portion 2131 of the bezel region light emitting control signal line 213a on the base substrate BS. The data line covering the first portion 2131 of the bezel region light emitting control signal line 213a can be disposed in a predetermined layer as needed.

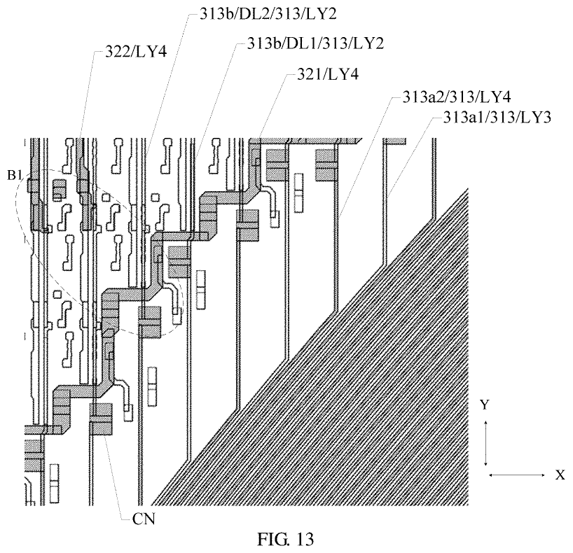

FIG. 13 is a plan view of a third conductive pattern layer and a fourth conductive pattern layer in a display panel provided by an embodiment of the present disclosure. As illustrated in FIG. 13, the second bezel region data line 313a2 is connected with the display region data line 313b connected thereto at a connection position CN, and the first bezel region data line 313a and the display region data line 313b connected thereto are integrally formed.

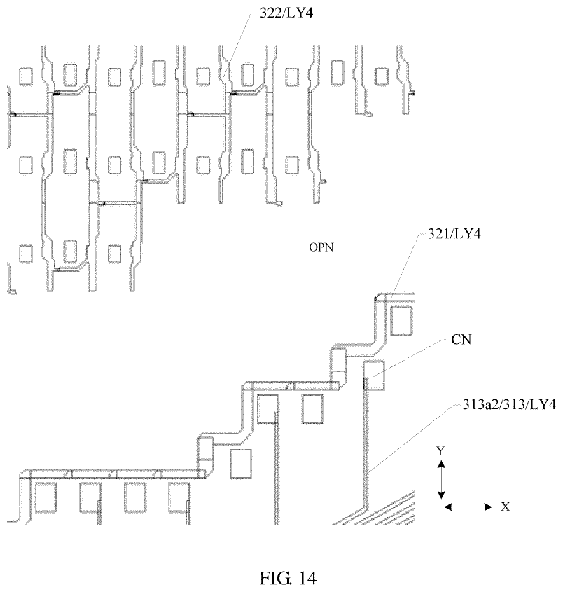

FIG. 14 is a plan view of a fourth conductive pattern layer in a display panel provided by an embodiment of the present disclosure. As illustrated in FIG. 14, the fourth conductive pattern layer LY4 includes a first conductive line 321, a second bezel region data line 313a2, and a second conductive line 322. The second conductive line 322 may be in a meshed shape, but is not limited thereto. As illustrated in FIG. 14, the first conductive line 321 is broken at the light transmission region R1, that is, the first conductive line 321 is disposed around the light transmission region R1 and has an opening OPN at the light transmission region.

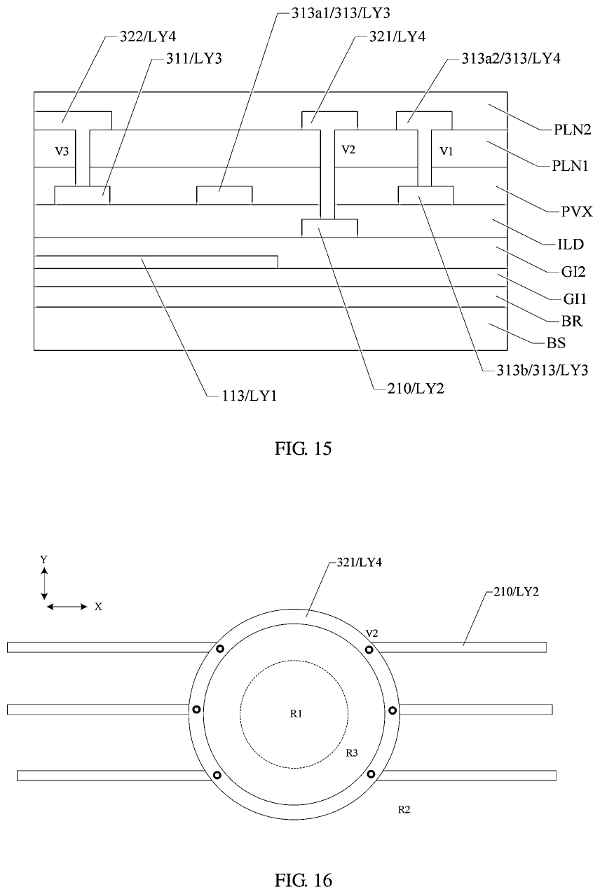

FIG. 15 is a cross-sectional view of a display panel provided by an embodiment of the present disclosure. For example, FIG. 15 can be a cross-sectional view of a partial structure in the dashed box B1 in FIG. 13. As illustrated in FIG. 13 and FIG. 15, the second bezel region data line 313a2 is connected with one display region data line 313b through a via hole V1 penetrating the first planarization layer PLN1 and the passivation layer PVX.

As illustrated in FIG. 15, the second conductive pattern layer LY2 includes an initialization signal line 210, the first conductive line 321 is connected with the initialization signal line 210 through a via hole V2 penetrating the first planarization layer PLN1, the passivation layer PVX and the interlayer insulation layer ILD, and the initialization signal line 210 is connected in parallel with the first conductive line 321 to reduce the resistance of the signal line.

As illustrated in FIG. 15, the third conductive pattern layer LY3 includes a first power line 311, and the second conductive line 322 is connected with the first power line 311 through a via hole V3 penetrating the first planarization layer PLN1 and the passivation layer PVX.

For example, as illustrated in FIG. 13 and FIG. 15, the first bezel region data line 313a1 and the display region data line 313b connected thereto are integrated, and the second bezel region data line 313a2 and the display region data line 313b connected thereto are connected through a via hole V1.

For example, as illustrated in FIG. 15, the initialization signal line 210 is located at a side of the gate line 113 away from the base substrate BS, the first conductive line 321 is located in the same layer as the second bezel region data line 313a2, and the first conductive line 321 is connected with the initialization signal line 210 through a via hole V2.

FIG. 16 is a plan view of an initialization signal line and a second conductive line in a display panel provided by an embodiment of the present disclosure. For example, as illustrated in FIG. 14 and FIG. 16, the first conductive line 321 is disposed around the light transmission region R1 and forms an outer boundary of the bezel region R3. The first conductive line 321 in FIG. 16 is illustrated as a circle, but the shape of the first conductive line 321 is not limited thereto, and can be arranged as needed. The first conductive line 321 forms a closed structure, such as an annular structure, but is not limited to this case.

For example, referring to FIG. 13, FIG. 14, and FIG. 16, the connection position of the second bezel region data line 313a2 and the display region data line 313b connected thereto is located at the inner side of the first conductive line 321. The inner side of the first conductive line 321 is located within the range enclosed by the first conductive line 321.

For example, referring to FIG. 13, FIG. 14 and FIG. 15, the second conductive line 322 is located in the same layer as the second bezel region data line 313a2, the second conductive line 322 is arranged around the first conductive line 321, and the second conductive line 322 is insulated from the first conductive line 321.

FIG. 11 to FIG. 15 are illustrated by taking that among the first data line DL1 (referring to FIG. 13) and the second data line DL2 (referring to FIG. 13) which are adjacent to each other, the first data line DL1 is located in the third conductive pattern layer LY3, the second bezel region data line 313a2 of the second data line DL2 is located in the fourth conductive pattern layer LY4, and other parts of the second data line DL2 are located in the third conductive pattern layer LY3 as an example, but are not limited to this case. In some other embodiments, the first data line DL1 and the second data line DL2 which are adjacent to each other can be located in the third conductive pattern layer LY3 and the fourth conductive pattern layer LY4, respectively. In this case, the second conductive line 322 can extend along the second direction Y in the display region.

FIG. 11 to FIG. 15 are illustrated by taking that the bezel region gate line 113a overlaps with the first bezel region data line 313a1, and the bezel region light emitting control signal line 213a overlaps with the second bezel region data line 313a2 as an example, but are not limited to this case. In some other embodiments, other arrangements can also be adopted.

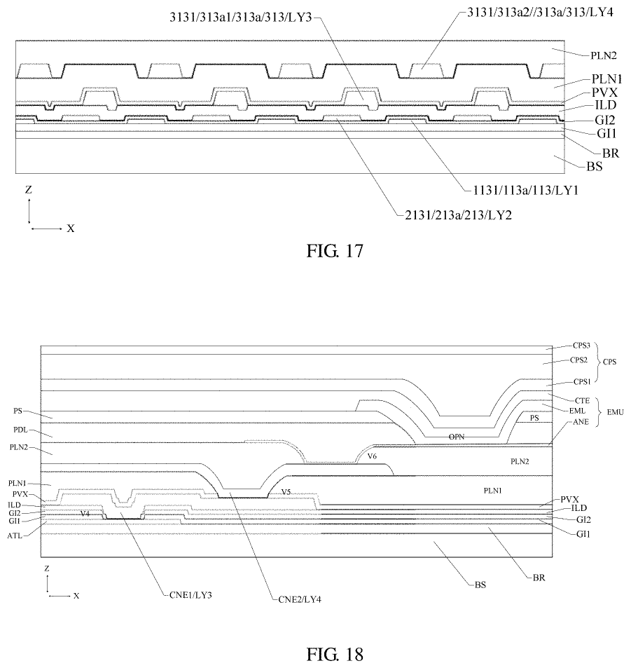

FIG. 17 is a cross-sectional view of a display panel provided by an embodiment of the present disclosure. As illustrated in FIG. 17, the bezel region gate line 113a overlaps with the second bezel region data line 313a2, and the bezel region light emitting control signal line 213a overlaps with the first bezel region data line 313a1.

Therefore, in the embodiments of the present disclosure, one of the bezel region gate line 113a and the bezel region light emitting control signal line 213a overlaps with the first bezel region data line 313a1, and the other of the bezel region gate line 113a and the bezel region light emitting control signal line 213a overlaps with the second bezel region data line 313a2.

For example, as illustrated in FIG. 17, in the bezel region R3, the gate line 113 is closer to the base substrate BS than the light emitting control signal line 213, and a second gate insulation layer GI2 is provided between the gate line 113 and the light emitting control signal line 213. That is, as illustrated in FIG. 17, the bezel region gate line 113a is closer to the base substrate BS than the bezel region light emitting control signal line 213a, and a second gate insulation layer GI2 is provided between the bezel region gate line 113a and the bezel region light emitting control signal line 213a.

For example, as illustrated in FIG. 17, an interlayer insulation layer ILD is provided between the light emitting control signal line 213 and the first bezel region data line 313a1.

For example, as illustrated in FIG. 17, the display panel further includes a second planarization layer PLN2, and the second planarization layer PLN2 covers the second bezel region data line 313a2.

For example, the material of at least one selected from the group consisting of the first bezel region data line 313a1, the second bezel region data line 313a2, the gate line 113, and the light emitting control signal line 213 includes metal or alloy.

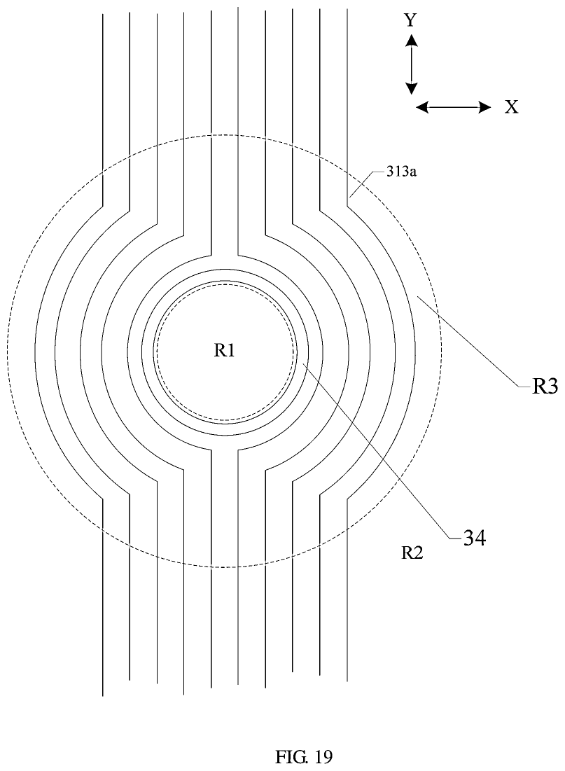

FIG. 18 is a cross-sectional view of a display panel provided by an embodiment of the present disclosure. The display panel illustrated in FIG. 18 illustrates a structure within the display region R2 of the display panel, that is, the structure of a normal light emitting region. For example, as illustrated in FIG. 18, the display panel includes a base substrate BS, a barrier layer BR is provided on the base substrate BS; an active layer ATL is provided on the barrier layer BR, the active layer ATL includes a source region, a drain region, and a channel between the source region and the drain region; the source region or the drain region of the active layer ATL is connected with a connection electrode CNE1, the connection electrode CNE1 is connected with the active layer ATL through a via hole V4 penetrating an interlayer insulation layer ILD, a second gate insulation layer GI2 and a first gate insulation layer GIL The connection electrode CNE1 is located in the third conductive pattern layer LY3, and a passivation layer PVX and a first planarization layer PLN1 are arranged at a side of the third conductive pattern layer LY3 away from the base substrate BS. A connection electrode CNE2 is located in the fourth conductive pattern layer LY4, and the connection electrode CNE2 is connected with the connection electrode CNE1 through a via hole V5 penetrating the passivation layer PVX and the first planarization layer PLN1.

As illustrated in FIG. 18, the display panel further includes a light emitting unit EMU, the light emitting unit EMU includes an anode ANE, a light emitting functional layer EML and a cathode CTE; the anode ANE is disposed on the fourth conductive pattern layer LY4, and the anode ANE is connected with the connection electrode CNE2 through a via hole V6 penetrating the second planarization layer PLN2. The display panel further includes an encapsulation layer CPS, and the encapsulation layer CPS includes a first encapsulation layer CPS1, a second encapsulation layer CPS2 and a third encapsulation layer CPS3. For example, the first encapsulation layer CPS1 and the third encapsulation layer CPS3 are inorganic material layers, and the second encapsulation layer CPS2 is an organic material layer.

As illustrated in FIG. 18, the display panel further includes a pixel definition layer PDL and a spacer PS. The pixel definition layer PDL includes an opening OPN, the opening OPN is configured to define a light emitting area of the display pixel unit, and the spacer PS is configured to support a fine metal mask when forming the light emitting functional layer EML.

The light emitting unit EMU includes an organic light emitting diode. The light emitting functional layer EML is located between the cathode CTE and the anode ANE. The light emitting functional layer EML at least includes a light emitting layer, and can further includes at least one selected from the group consisting of a hole transport layer, a hole injection layer, an electron transport layer and an electron injection layer.

For example, one of the anode and the cathode of the light emitting unit EMU is electrically connected with a driving transistor, and the driving transistor is configured to provide a driving current for the light emitting unit EMU to drive the light emitting unit EMU to emit light.

FIG. 19 is a partial view of a display panel provided by an embodiment of the present disclosure. For example, as illustrated in FIG. 19, the display panel further includes an isolation pillar 34, the isolation pillar 34 is located in the bezel region R3 and arranged around the light transmission region R1, the isolation pillar 34 is located at a side of the plurality of bezel region data lines 313a close to the light transmission region R1, and the isolation pillar 34 forms the inner boundary of the bezel region R3. For example, the isolation pillar 34 is made of a metal material.

For example, the isolation pillar 34 is disposed in the same layer as the first bezel region data line 313a1 or the second bezel region data line 313a2. That is, the isolation pillar 34 is located in the third conductive pattern layer LY3 or in the fourth conductive pattern layer LY4.

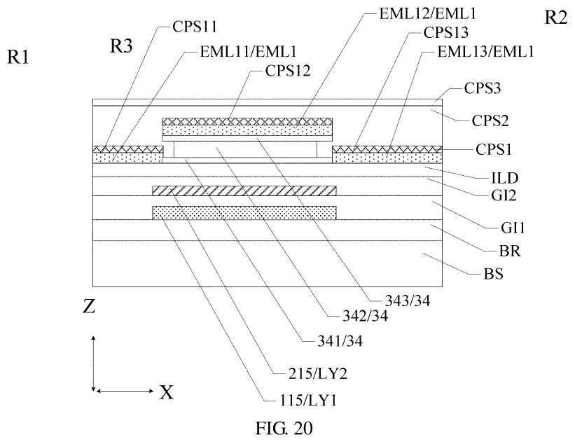

FIG. 20 is a partial view of a display panel provided by an embodiment of the present disclosure. As illustrated in FIG. 20, the isolation pillar 34 includes a first sub-layer 341, a second sub-layer 342 and a third sub-layer 343, the first sub-layer 341 is closer to the base substrate than the second sub-layer 342, the second sub-layer 342 is closer to the base substrate than the third sub-layer 343, the size of the second sub-layer 342 along a radial direction of the light transmission region R1 is less than the size of the first sub-layer 341 along the radial direction of the light transmission region R1, and the size of the second sub-layer 342 along the radial direction of the light transmission region R1 is less than the size of the third sub-layer 343 along the radial direction of the light transmission region RE For example, the materials of the first sub-layer 341 and the third sub-layer 343 both include Ti, and the material of the second sub-layer 342 includes Al, but they are not limited thereto.

For example, as illustrated in FIG. 20, the organic light emitting diode includes a light emitting functional layer EML1, the light emitting functional layer EML1 includes a first portion EML11 located at a side of the isolation pillar 34 away from the light transmission region R1 and a second portion EML12 located on the isolation pillar 34, and the first portion EML11 of the light emitting functional layer EML1 and the second portion EML12 of the light emitting functional layer are broken at a side edge of the isolation pillar 34. The light emitting functional layer EML1 can be a light emitting functional layer in the form of an entire layer, but is not limited thereto. The light emitting functional layer EML1 can be manufactured by using an opening mask, but is not limited to this case.

Due to the inward arrangement of the second sub-layer 342 in the isolation pillar 34, when the light emitting functional layer EML1 is formed on the isolation pillar 34, the light emitting functional layer EML1 is broken, so that the part of the light emitting functional layer EML1 located in the display region R2 is prevented from being eroded when the external environment such as water and oxygen erodes the light emitting functional layer EML1, and the display effect is prevented from being affected.

For example, as illustrated in FIG. 20, the light emitting functional layer EML1 further includes a third portion EML13 located at a side of the isolation pillar 34 away from the light transmission region R1, and the third portion EML13 and the second portion EML12 are broken at a side edge of the isolation pillar 34.

For example, as illustrated in FIG. 20, the display panel further includes a first encapsulation layer CPS1, a second encapsulation layer CPS2 and a third encapsulation layer CPS3. The first encapsulation layer CPS1 includes a first portion CPS11 located at a side of the isolation pillar 34 close to the light transmission region R1 and a second portion CPS12 located on the isolation pillar 34, and the first portion CPS11 and the second portion CPS12 are broken at a side edge of the isolation pillar 34. The materials of the first encapsulation layer CPS1, the second encapsulation layer CPS2 and the third encapsulation layer CPS3 can be selected as described above.

For example, as illustrated in FIG. 20, the first encapsulation layer CPS1 further includes a third portion CPS13 located at a side of the isolation pillar 34 away from the light transmission region R1, and the third portion CPS13 and the second portion CPS12 are broken at a side edge of the isolation pillar 34.

For example, as illustrated in FIG. 20, the second encapsulation layer CPS2 is provided between the first portion EML11 of the light emitting functional layer EML1 and the second portion EML12 of the light emitting functional layer, and the second encapsulation layer CPS2 is provided between the third portion EML13 of the light emitting functional layer EML1 and the second portion EML12 of the light emitting functional layer.

FIG. 20 further illustrates an element 115 and an element 215. The element 115 is located in the first conductive pattern layer LY1, and the element 215 is located in the second conductive pattern layer LY2.

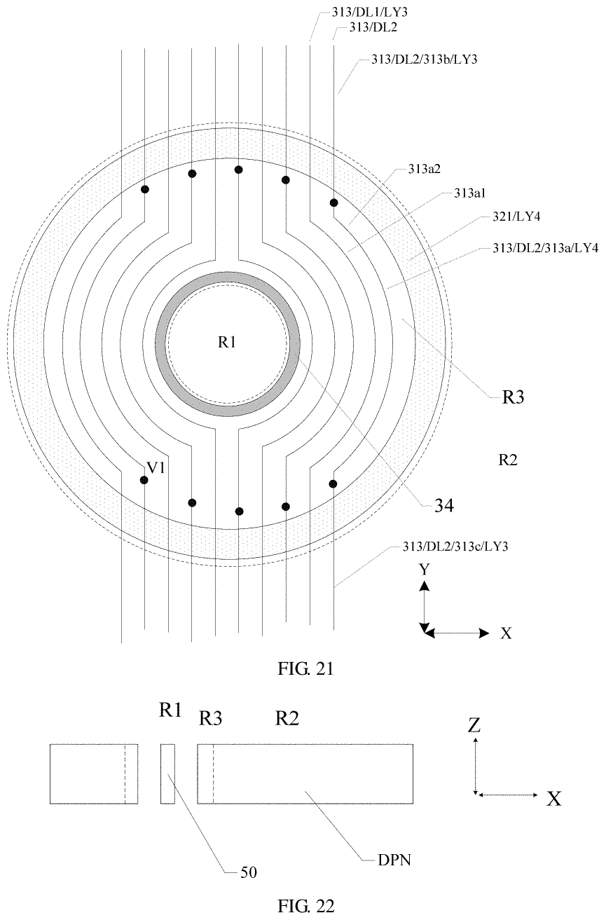

FIG. 21 is a partial view of a display panel provided by an embodiment of the present disclosure. Compared with FIG. 19, the display panel illustrated in FIG. 21 further illustrates a first conductive line 321. As illustrated in FIG. 21, the isolation pillar 34 defines the inner boundary of the bezel region R3, and the first conductive line 321 defines the outer boundary of the bezel region R3.

FIG. 22 is a schematic diagram of a display panel provided by an embodiment of the present disclosure. As illustrated in FIG. 4 and FIG. 22, the light transmission region R1 of the display panel DPN is a region where a hole is formed. As illustrated in FIG. 22, a sensor 50 is provided in the region where a hole is formed. For example, the sensor 50 can be partially disposed in the region where a hole is formed, or can be entirely disposed in the region where a hole is formed, which is not limited thereto. For example, the sensor includes a camera, but is not limited thereto. After the encapsulation layer is formed, the part of the display panel located in the light transmission region R1 is removed to form a hole, so as to form the display panel.

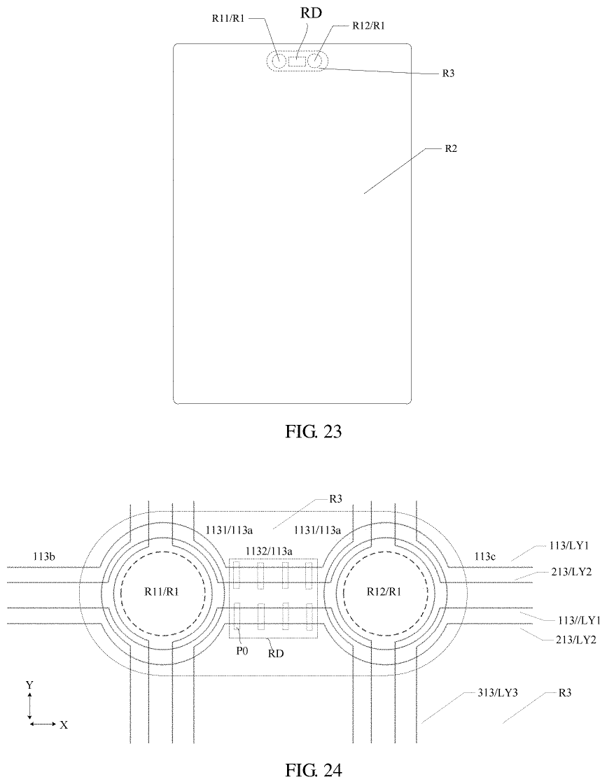

FIG. 23 is a schematic diagram of a display panel provided by an embodiment of the present disclosure. As illustrated in FIG. 23, the light transmission region R1 includes a first light transmission region R1 and a second light transmission region R12. The first light transmission region R1 and the second light transmission region R12 are both regions in each of which a hole is formed. The region between the first light transmission region R1 and the second light transmission region R12 is also a bezel region R3.

FIG. 24 is a partial view of FIG. 23. As illustrated in FIG. 24, the bezel region gate line 113a includes a second portion 1132 located between the first light transmission region R1 and the second light transmission region R12. The second portion 1132 of the bezel region gate line 113a is provided with a dummy pixel unit to further increase the load of the gate line, reduce the missing load of the gate line, and alleviate or avoid the lateral Mura. FIG. 23 and FIG. 24 illustrate a dummy region RD, and FIG. 24 illustrates a plurality of dummy pixel units P0 located in the dummy region RD. It should be noted that the number of dummy pixel units P0 is not limited to that illustrated in the figure, but can be arranged as needed.

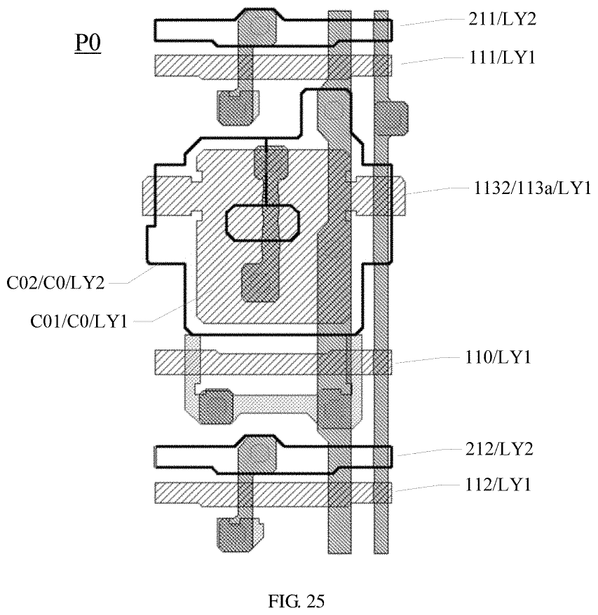

FIG. 25 is a plan view of a dummy pixel unit at a second portion of a bezel region gate line. The second portion 1132 of the bezel region gate line 113a is connected with the first electrode plate C01 of the load capacitor C0, and the second electrode plate C02 of the load capacitor C0 is opposite to the first electrode plate C01 of the load capacitor C0. The load capacitor C0 can greatly increase the load of the gate line, which is equivalent to forming, by using the gate line and the second electrode plate C02, a capacitor with a capacitance greater than the capacitance of a storage capacitor C1 (to be described later) of the display pixel unit in the display region. Thus, the load of the gate line (scan signal SCAN) of a dummy pixel unit P0 can be 10-20 times the load in the case where the load capacitor C0 is not provided. For example, according to the capacitance to be compensated and the number of dummy pixel units, the overlapping area of the load capacitor C0 of the dummy pixel unit can be designed to obtain the capacitance to be compensated.

This design makes use of the space where the dummy pixel unit was originally placed, and effectively compensates the capacitance of the gate line in the vicinity of the hole, thus solving the problem of lateral Mura at the hole.

For example, as illustrated in FIG. 25, the second portion 1132 of the bezel region gate line 113a and the first electrode plate C01 of the load capacitor C0 are integrally formed, and can be formed by the same film layer using the same patterning process, and both can be located in the first conductive pattern layer LY1. For example, as illustrated in FIG. 25, the second portion 1132 of the bezel region gate line 113a and the first electrode plate C01 of the load capacitor C0 are integrated.

For example, as illustrated in FIG. 25, the second electrode plate C02 of the load capacitor C0 is connected with the first power line 311, and the first power line 311 is configured to provide a constant voltage signal.

For example, as illustrated in FIG. 25, the second electrode plate C02 of the load capacitor C0 partially overlaps with the second portion 1132 of the bezel region gate line 113a.

In FIG. 25, the light emitting control signal line 110 is located in the first conductive pattern layer LY1, but is not limited thereto. In some other embodiments, the light emitting control signal line 110 can also be located in the second conductive pattern layer LY2.

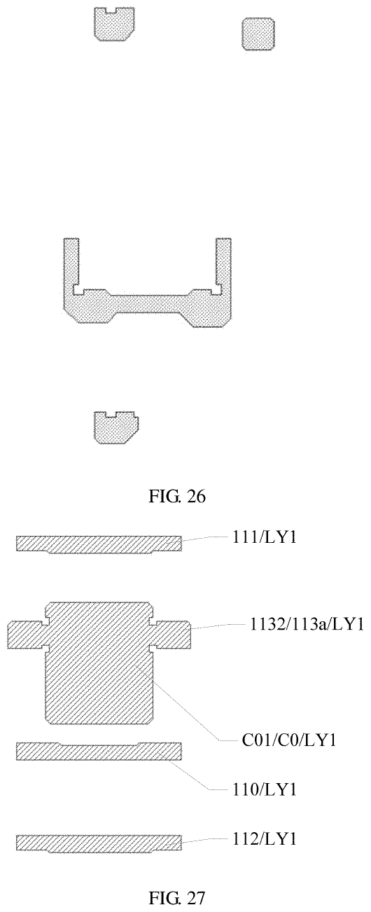

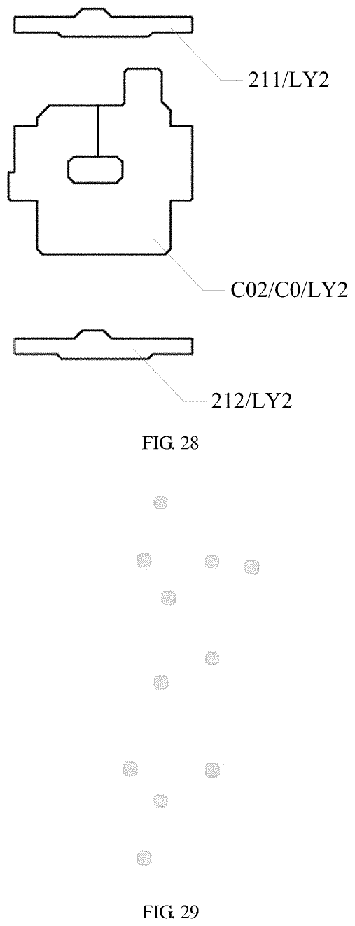

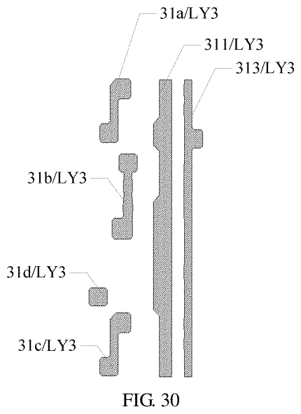

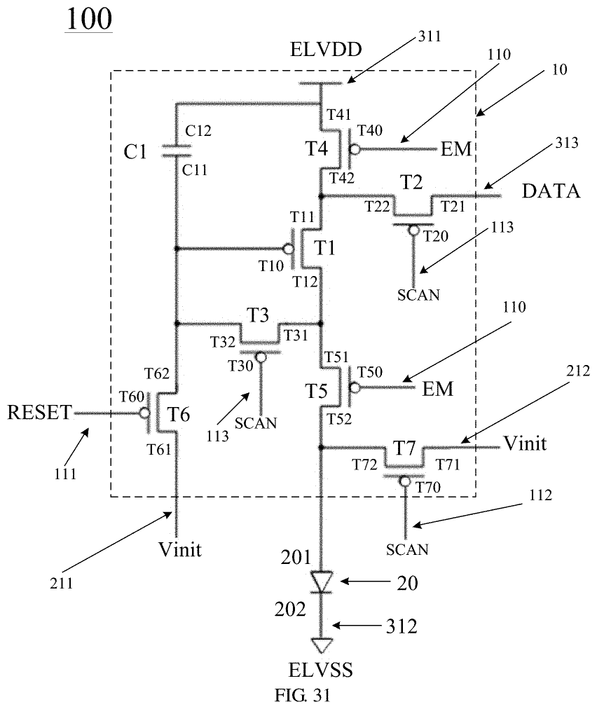

FIG. 26 is a pattern of an active layer of the dummy pixel unit in FIG. 25. FIG. 27 is a pattern of a first conductive pattern layer of the dummy pixel unit in FIG. 25. As illustrated in FIG. 27, in the first conductive pattern layer LY1, the second portion 1132 of the gate line 113 is integrally formed with the first electrode plate C01 of the load capacitor C0. FIG. 28 is a pattern of a second conductive pattern layer of the dummy pixel unit in FIG. 25. The second conductive pattern layer LY2 includes the second electrode plate C02 of the load capacitor C0. As illustrated in FIG. 28, the second electrode plate C02 of the load capacitor C0 has an opening at the intermediate position thereof. FIG. 29 is a pattern of an insulation layer of the dummy pixel unit in FIG. 25, and illustrates a via hole penetrating the insulation layer. The insulation layer includes at least one selected from the group consisting of a first gate insulation layer, a second gate insulation layer and an interlayer insulation layer. FIG. 30 is a pattern of a third conductive pattern layer of the dummy pixel unit in FIG. 25. The third conductive pattern layer LY3 includes a first connection electrode 31a, a second connection electrode 31b, a third connection electrode 31c, a fourth connection electrode 31d, a data line 313, and a first power line 311. For example, in order to increase the load of the gate line, the second connection electrode 31b is connected with the second electrode plate C02 of the load capacitor C0 through a via hole, which is not limited to this case.

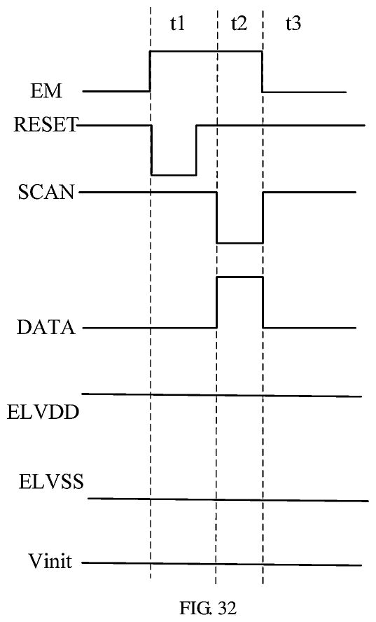

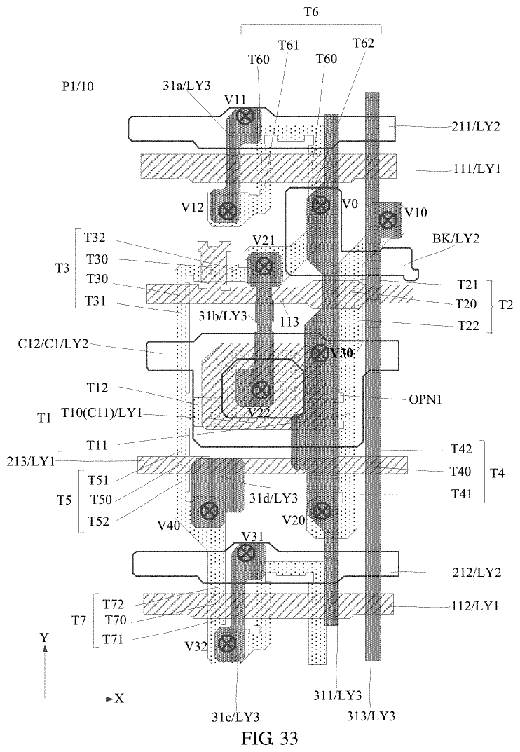

FIG. 31 is a schematic diagram of a pixel circuit structure of a display panel provided by an embodiment of the present disclosure. FIG. 32 is a timing signal diagram of a pixel unit in a display panel provided by an embodiment of the present disclosure. FIG. 33 is a plan view of a display substrate provided by an embodiment of the present disclosure. Referring to FIG. 31 and FIG. 6, the display panel 100 includes a plurality of display pixel units P1 arranged in a matrix, and each display pixel unit P1 includes a pixel circuit structure 10, a light emitting element 20, a gate line 113, a data line 313 and a voltage signal line. For example, the light emitting element 20 is an organic light emitting diode (OLED), and the light emitting element 20 emits red light, green light, blue light, or white light, etc., under the drive of a pixel circuit structure 10 corresponding thereto. One or a plurality of voltage signal lines can be provided. For example, as illustrated in FIG. 31, the voltage signal line includes at least one selected from the group consisting of a first power line 311, a second power line 312, a light emitting control signal line 110, a first initialization signal line 211, a second initialization signal line 212, a first reset control signal line 111, a second reset control signal line 112, etc. The gate line 113 is configured to provide a scan signal SCAN to the pixel circuit structure 10. The data line 313 is configured to provide a data signal DATA to the pixel circuit structure 10. For example, one pixel includes a plurality of pixel units. One pixel can include a plurality of pixel units emitting light of different colors. For example, one pixel includes a pixel unit emitting red light, a pixel unit emitting green light and a pixel unit emitting blue light, but is not limited to this case. The number of pixel units included in one pixel and the light emitting condition of each pixel unit can be determined as needed.

The display pixel unit P1 can emit light. The structure of the dummy pixel unit P0 is formed by omitting some line structure of the display pixel unit P1. For example, the pixel circuit of the dummy pixel unit P0 is incomplete. The pixel circuit of the dummy pixel unit P0 being incomplete refers to that the pixel circuit of the dummy pixel unit P0 may not have at least one of elements or components in the pixel circuit structures 10. The pixel definition layer has no opening at the dummy pixel unit P0, or the dummy pixel unit P0 has no anode, so that the dummy pixel unit P0 does not emit light.

For example, the first power line 311 is configured to provide a constant first voltage signal ELVDD to the pixel circuit structure 10, the second power line 312 is configured to provide a constant second voltage signal ELVSS to the pixel circuit structure 10, and the first voltage signal ELVDD is greater than the second voltage signal ELVSS. The light emitting control signal line 110 is configured to provide a light emitting control signal EM to the pixel circuit structure 10. The first initialization signal line 211 and the second initialization signal line 212 are configured to provide an initialization signal Vint to the pixel circuit structure 10, the first reset control signal line 111 is configured to provide a reset control signal RESET to the pixel circuit structure 10, and the second reset control signal line 112 is configured to provide a scan signal SCAN to the pixel circuit structure 10. The initialization signal Vint is a constant voltage signal, and the magnitude thereof can be between the first voltage signal ELVDD and the second voltage signal ELVSS, but is not limited to thereto. For example, the initialization signal Vint can be less than or equal to the second voltage signal ELVSS.

As illustrated in FIG. 31 and FIG. 33, the pixel circuit structure 10 includes a driving transistor T1, a data writing transistor T2, a threshold compensation transistor T3, a first light emitting control transistor T4, a second light emitting control transistor T5, a first reset transistor T6, a second reset transistor T7, and a storage capacitor C1. The driving transistor T1 is electrically connected with the light emitting element 20, and outputs a driving current to drive the light emitting element 20 to emit light under the control of signals, such as the scan signal SCAN provide by the gate line 113, the data signal DATA, the first voltage signal ELVDD, the second voltage signal ELVSS, etc.

In the pixel unit of the organic light emitting diode display panel, the driving transistor is connected with the organic light emitting element, and outputs a driving current to the organic light emitting element under the control of signals such as a data signal and a scan signal, etc., so as to drive the organic light emitting element to emit light.

For example, the display panel 100 provided by the embodiments of the present disclosure further includes a data driving circuit and a scan driving circuit. The data driving circuit is configured to provide the data signal DATA to the display pixel unit P1 according to an instruction of a control circuit; the scan driving circuit is configured to provide signals, such as the light emitting control signal EM, the scan signal SCAN, the reset control signal RESER, etc., to the display pixel unit P1 according to an instruction of the control circuit. For example, the control circuit includes an external integrated circuit (IC), but is not limited thereto. For example, the scan driving circuit is a GOA (Gate driver On Array) structure mounted on the display panel, or a driving chip (IC) structure bonding to the display panel. For example, different driving circuits can also be adopted to provide the light emitting control signal EM and the scan signal SCAN, respectively. For example, the display panel 100 further includes a power source (not illustrated in the figure) to provide the above voltage signals, the power source can be a voltage source or a current source as needed, and the power source is configured to provide the first voltage signal ELVDD, the second power voltage ELVSS, the initialization signal Vint, etc., to the display pixel unit P1 through the first power line 311, the second power line 312, and the initialization signal lines (the first initialization signal line 211 and the second initialization signal line 212), respectively.

As illustrated in FIG. 31 and FIG. 33, the second electrode C12 of the storage capacitor C1 is electrically connected with the first power line 311, and the first electrode C11 of the storage capacitor C1 is electrically connected with the second electrode T32 of the threshold compensation transistor T3. The gate electrode T20 of the data writing transistor T2 is electrically connected with the gate line 113, and the first electrode T21 and the second electrode T22 of the data writing transistor T2 are electrically connected with the data line 313 and the first electrode T11 of the driving transistor T1, respectively. The gate electrode T30 of the threshold compensation transistor T3 is electrically connected with the gate line 113, the first electrode T31 of the threshold compensation transistor T3 is electrically connected with the second electrode T12 of driving transistor T1, and the second electrode T32 of the threshold compensation transistor T3 is electrically connected with the gate electrode T10 of driving transistor T1.

For example, as illustrated in FIG. 31 and FIG. 33, the gate electrode T40 of the first light emitting control transistor T4 and the gate electrode T50 of the second light emitting control transistor T5 are both connected with the light emitting control signal line 110.

For example, as illustrated in FIG. 31 and FIG. 33, the first electrode T41 and the second electrode T42 of the first light emitting control transistor T4 are electrically connected with the first power line 311 and the first electrode T11 of the driving transistor T1, respectively. The first electrode T51 and the second electrode T52 of the second light emitting control transistor T5 are electrically connected with the second electrode T12 of the driving transistor T1 and the first electrode 201 of the light emitting element 20, respectively. The second electrode 202 (which may be a common electrode, e.g., cathode, of the OLEDs) of the light emitting element 20 is electrically connected with the second power line 312.

For example, as illustrated in FIG. 31 and FIG. 33, the gate electrode T60 of the first reset transistor T6 is electrically connected with the first reset control signal line 111, the first electrode T61 of the first reset transistor T6 is electrically connected with the first initialization signal line 211, and the second electrode T62 of the first reset transistor T6 is electrically connected with the gate electrode T10 of the driving transistor T1. The gate electrode T70 of the second reset transistor T7 is electrically connected with the second reset control signal line 112, the first electrode T71 of the second reset transistor T7 is electrically connected with the second initialization signal line 212, and the second electrode T72 of the second reset transistor T7 is electrically connected with the first electrode 201 of the light emitting element 20.

It should be noted that the transistors adopted in any embodiment of the present disclosure can be thin film transistors, field effect transistors or other switching elements with the same characteristics. The source electrode and the drain electrode of a transistor adopted here can be symmetrical in structure, so there may be no difference in structure between the source electrode and the drain electrode. In an embodiment of the present disclosure, in order to distinguish the two electrodes of the transistor other than the gate electrode, it is directly described that one electrode is the first electrode and the other electrode is the second electrode, so the first electrode and the second electrode of all or part of the transistors in the embodiment of the present disclosure can be interchanged as needed. For example, as to the transistor described in the embodiment of the present disclosure, the first electrode can be a source electrode while the second electrode can be a drain electrode. Or, the first electrode of the transistor is a drain electrode while the second electrode of the transistor is a source electrode.

In addition, transistors can be divided into N-type and P-type transistors according to their characteristics. The embodiments of the present disclosure are illustrated by taking that the transistors are P-type transistors as an example. Based on the description and teaching of the implementation of the present disclosure, those skilled in the art can easily think of an implementation in which at least some transistors in the pixel circuit structure of the embodiments of the present disclosure are N-type transistors, that is, N-type transistors or a combination of N-type transistors and P-type transistors are adopted. Therefore, these implementations are also within the protection scope of the present disclosure.

Hereinafter, a driving method of one pixel unit in the display panel provided by an embodiment of the present disclosure will be described with reference to FIG. 6 and FIG. 32.

As illustrated in FIG. 32, within a display time period of one frame, the driving method of the pixel unit includes a first reset phase t1, a data writing and threshold compensation and second reset phase t2, and a light emitting phase t3.

In the first reset phase t1, the light emitting control signal EM is set to be a turn-off voltage; the reset control signal RESET is set to be a turn-on voltage; and the scan signal SCAN is set to be a turn-off voltage.

In the data writing and threshold compensation and second reset phase t2, the light emitting control signal EM is set to be a turn-off voltage; the reset control signal RESET is set to be a turn-off voltage; and the scan signal SCAN is set to be a turn-on voltage.

In the light emitting phase t3, the light emitting control signal EM is set to be a turn-on voltage; the reset control signal RESET is set to be a turn-off voltage; and the scan signal SCAN is set to be a turn-off voltage.

As illustrated in FIG. 32, the first voltage signal ELVDD, the second voltage signal ELVSS, and the initialization signal Vint are all constant voltage signals; and the initialization signal Vint is between the first voltage signal ELVDD and the second voltage signal ELVSS.

For example, in the embodiment of the present disclosure, the turn-on voltage refers to a voltage that can cause a first electrode and a second electrode of a corresponding transistor to be turned on, and the turn-off voltage refers to a voltage that can cause a first electrode and a second electrode of a corresponding transistor to be turned off. In the case where the transistor is a transistor of P-type, the turn-on voltage is a low voltage (e.g., 0 V), and the turn-off voltage is a high voltage (e.g., 5 V); in the case where the transistor is a transistor of N-type, the turn-on voltage is a high voltage (e.g., 5 V), and the turn-off voltage is a low voltage (e.g., 0 V). Driving waveforms illustrated in FIG. 32 are all described by taking transistors of P-type as an example, that is, the turn-on voltage is a low voltage (e.g., 0 V), and the turn-off voltage is a high voltage (e.g., 5 V).

Referring to FIG. 6 and FIG. 32 together, in the first reset phase t1, the light emitting control signal EM is at a turn-off voltage; the reset control signal RESET is at a turn-on voltage; and the scan signal SCAN is at a turn-off voltage. In this case, the first reset transistor T6 is in a turn-on state; while the data writing transistor T2, the threshold compensation transistor T3, the first light emitting control transistor T4, and the second light emitting control transistor T5 are in a turn-off state. An initialization signal (an initialization voltage) Vint is transmitted to the gate electrode of the driving transistor T1 by the first reset transistor T6 and then is stored by the storage capacitor C1, so as to reset the driving transistor T1 and eliminate the data stored during emitting light in the last time (a previous frame).

In the data writing and threshold compensation and second reset phase t2, the light emitting control signal EM is at a turn-off voltage; the reset control signal RESET is at a turn-off voltage; and the scan signal SCAN is at a turn-on voltage. In this case, the data writing transistor T2 and the threshold compensation transistor T3 are in a turn-on state; the second reset transistor T7 is in a turn-on state; and the second reset transistor T7 transmits the initialization signal Vint to the first electrode of the light emitting element 20 to reset the light emitting element 20; while the first light emitting control transistor T4, the second light emitting control transistor T5, the first reset transistor T6, and the second reset transistor T7 are in a turn-off state. At this time, the data writing transistor T2 transmits the data signal voltage VDATA to the first electrode of the driving transistor T1, that is, the data writing transistor T2 receives the scan signal SCAN and the data signal DATA and writes the data signal DATA into the first electrode of the driving transistor T1 according to the scan signal SCAN. The threshold compensation transistor T3 is turned on to connect the driving transistor T1 into a diode structure, so that the gate electrode of the driving transistor T1 can be charged. After the charging is completed, a voltage on the gate electrode of the driving transistor T1 is VDATA+Vth, where VDATA is a data signal voltage and Vth is a threshold voltage of the driving transistor T1, that is, the threshold compensation transistor T3 receives the scan signal SCAN and performs threshold voltage compensation on the voltage on the gate electrode of the driving transistor T1. In this phase, a voltage difference between both ends of the storage capacitor C1 is ELVDD-VDATA −Vth.

In the light emitting phase t3, the light emitting control signal EM is at a turn-on voltage; the reset control signal RESET is at a turn-off voltage; and the scan signal SCAN is at a turn-off voltage. The first light emitting control transistor T4 and the second light emitting control transistor T5 are in a turn-on state; while the data writing transistor T2, the threshold compensation transistor T3, the first reset transistor T6, and the second reset transistor T7 are in a turn-off state. The first voltage signal ELVDD is transmitted to the first electrode of the driving transistor T1 through the first light emitting control transistor T4; the voltage on the gate electrode of the driving transistor T1 is maintained at VDATA+Vth; and a light emitting current I flows into the light emitting element 20 through the first light emitting control transistor T4, the driving transistor T1, and the second light emitting control transistor T5, so that the light emitting element 20 emits light. That is, the first light emitting control transistor T4 and the second light emitting control transistor T5 receive the light emitting control signal EM, and control the light emitting element 20 to emit light according to the light emitting control signal EM. The light emitting current I satisfies the following saturation current formula:

K(Vgs−Vth)²=K(VDATA+Vth−ELVDD−Vth)²=K(VDATA−ELVDD)²

where

$$K = 0.5 {μ}_{n} C o x \frac{W}{L} ,$$

μₙ is channel mobility of the driving transistor, Cox is a channel capacitance per unit area of the driving transistor T1, W and L are a channel width and a channel length of the driving transistor T1, respectively, and Vgs is a voltage difference between the gate electrode and the source electrode (i.e., the first electrode of the driving transistor T1 according to this embodiment) of the driving transistor T1.

It can be seen from the above formula that, the current flowing through the light emitting element 20 is independent of the threshold voltage of the driving transistor T1. Therefore, the pixel circuit structure is very well compensated for the threshold voltage of the driving transistor T1.

For example, a ratio of duration of the light emitting phase t3 to a display time period of one frame may be adjusted. In this way, light emitting brightness may be controlled by adjusting the ratio of the duration of the light emitting phase t3 to the display time period of one frame. For example, the ratio of the duration of the light emitting phase t3 to the display time period of one frame is adjusted by controlling the scan driving circuit 103 in the display panel or a driving circuit additionally provided.

For example, in some other embodiments, the first reset transistor T6 or the second reset transistor T7, etc. may not be provided, that is, the embodiments of the present disclosure are not limited to the specific pixel circuit illustrated in FIG. 6, and other pixel circuit that can implement compensation to the driving transistor may be used. Based on the description and teaching of the implementations of the present disclosure, other arrangements that can be easily conceived by those skilled in the art without any inventive work are within the protection scope of the present disclosure.

As illustrated in FIG. 33, the data line 313 is electrically connected with the first electrode T21 of the data writing transistor T2 through a via hole V10, the first power line 311 is electrically connected with the first electrode T41 of the first light emitting control transistor T4 through a via hole V20, the first power line 311 is electrically connected with the second electrode C12 of the storage capacitor C1 through a via hole V30, and the first power line 311 is electrically connected with a conductive block BK through a via hole V0.

As illustrated in FIG. 33, one end of the first connection electrode 31a is electrically connected with the first initialization signal line 211 through a via hole V11, and the other end of the first connection electrode 31a is electrically connected with the first electrode T61 of the first reset transistor T6 through a via hole V12, so that the first electrode T61 of the first reset transistor T6 is electrically connected with the first initialization signal line 211. One end of the second connection electrode 31b is electrically connected with the second electrode T62 of the first reset transistor T6 through a via hole V21, and the other end of the second connection electrode 31b is electrically connected with the gate electrode T10 of the driving transistor T1 (i.e., the first electrode C11 of the storage capacitor C1) through a via hole V22, so that the second electrode T62 of the first reset transistor T6 is electrically connected with the gate electrode T10 of the driving transistor T1 (i.e., the first electrode C11 of the storage capacitor C1). One end of the third connection electrode 31c is electrically connected with the second initialization signal line 212 through a via hole V31, and the other end of the third connection electrode 31c is electrically connected with the first electrode T71 of the second reset transistor T7 through a via hole V32, so that the first electrode T71 of the second reset transistor T7 is electrically connected with the second initialization signal line 212. The fourth connection electrode 31d is electrically connected with the second electrode T52 of the second light emitting control transistor T5 through a via hole V40. After forming the third conductive pattern layer, the display substrate illustrated in FIG. 3 can be obtained.

As illustrated in FIG. 33, the second electrode C12 of the storage capacitor C1 has an opening OPN1, so that the other end of the second connection electrode 31b is electrically connected with the gate electrode T10 of the driving transistor T1 through the via hole V22.

The active layer can be formed by firstly forming a semiconductor pattern layer made of semiconductor material and then doping the semiconductor pattern layer with the first conductive pattern layer LY1 as a mask. The doping can adopt a heavy doping. The part of the semiconductor pattern layer covered by the first conductive pattern layer LY1 forms a channel, while the parts of the semiconductor pattern layer not covered by the first conductive pattern layer LY1 are conductive to form the source electrode and the drain electrode of a transistor. For example, the semiconductor material includes poly-silicon, but is not limited thereto.

As illustrated in FIG. 33, in order to reduce parasitic capacitance, the first power signal line 311 is narrowed at a position where the first power signal line 311 overlaps with a lateral signal line. For example, the first power signal line 311 is narrowed at a position where the first power signal line 311 overlaps with the gate line 113.

FIG. 33 illustrates an active layer, a first conductive pattern layer LY1, a second conductive pattern layer LY2, a third conductive pattern layer LY3, and via holes. The circle with a cross therein in FIG. 33 indicates a via hole. Elements in the same conductive pattern layer are formed by the same film layer using the same patterning process.

The pixel circuit of the display substrate illustrated in FIG. 33 can be as illustrated in FIG. 31. The embodiment of the present disclosure takes that the pixel circuit of the display panel has a 7T1C structure as an example, but is not limited to this case. The pixel circuit of the display substrate can also have a structure including other numbers of transistors, such as a 7T2C structure, a 6T1C structure, a 6T2C structure or a 9T2C structure, which is not limited in the embodiments of the present disclosure.

Referring to FIG. 25 and FIG. 33, as can be seen in the dummy pixel unit, it is equivalent to that the gate line 113 in the display pixel unit is combined with the first electrode C11 of the storage capacitor C11 to form the first electrode plate of the load capacitor in the dummy pixel unit, so as to provide a relatively large load capacitance.

For example, in the display panel illustrated in FIG. 33, a barrier layer BR and a first gate insulation layer GI1 are arranged between the base substrate and the first conductive layer LY1, a second gate insulation layer GI2 is arranged between the first conductive layer LY1 and the second conductive layer LY2, an interlayer insulation layer is arranged between the second conductive layer LY2 and the third conductive layer LY3, and the via hole penetrates at least one of the first gate insulation layer GIL the second gate insulation layer GI2 or the interlayer insulation layer ILD.

In the embodiment of the present disclosure, the barrier layer BR, the first gate insulation layer GIL the second gate insulation layer GI2, the interlayer insulation layer ILD, the passivation layer PVX, the first planarization layer PLN1, the second planarization layer PLN2, the pixel definition layer PDL and the support layer PS are all made of insulation materials. For example, the barrier layer BR, the first gate insulation layer GIL the second gate insulation layer GI2, the interlayer insulation layer ILD and the passivation layer PVX are made of inorganic insulation materials, and the first planarization layer PLN1, the second planarization layer PLN2, the pixel definition layer PDL and the support layer PS can be made of organic insulation materials, but are not limited thereto.

At least one embodiment of the present disclosure further provides a display device, which includes any one of the above display panels.

For example, the display device includes an OLED display device, or any product or apparatus including the OLED display device and having display function, such as a computer, a mobile phone, a watch, an electronic photo-frame, a navigator, etc.

What have been described above are only specific implementations of the present disclosure, the protection scope of the present disclosure is not limited thereto. Any changes or substitutions easily occur to those skilled in the art within the technical scope of the present disclosure should be covered in the protection scope of the present disclosure. Therefore, the protection scope of the present disclosure should be based on the protection scope of the claims.

What is claimed is:

1. A display panel, comprising:
a light transmission region;
a display region, arranged around the light transmission region or at a side of the light transmission region;
a bezel region, located between the light transmission region and the display region;
a plurality of data lines, located on a base substrate, comprising a plurality of bezel region data lines located in the bezel region and a plurality of display region data lines located in the display region, and the plurality of bezel region data lines being connected with the plurality of display region data lines, respectively; and
a plurality of gate lines located on the base substrate, comprising a plurality of bezel region gate lines located in the bezel region and a plurality of display region gate lines located in the display region, and the plurality of bezel region gate lines being connected with the plurality of display region gate lines, respectively,
wherein each of the plurality of bezel region gate lines comprises a first portion, each of the plurality of bezel region data lines comprises a first portion, an extending direction of the first portion of the bezel region gate line is same as an extending direction of the first portion of the bezel region data line, and the first portion of the bezel region gate line overlaps with the first portion of one of the plurality of bezel region data lines in a direction perpendicular to the base substrate.

2. The display panel according to claim 1, wherein a width of a part of the bezel region gate line overlapping with the bezel region data line is less than or equal to a width of the bezel region data line.

3. The display panel according to claim 1, wherein a length of a part of the bezel region gate line overlapping with the bezel region data line along an extending direction of the part of the bezel region gate line is less than a length of the first portion of the bezel region gate line.

4. The display panel according to claim 1, wherein a length of a part of the bezel region gate line overlapping with the bezel region data line along an extending direction of the part of the bezel region gate line is greater than a width of the bezel region data line.

5. The display panel according to claim 1, wherein the first portion of the bezel region gate line comprises a curved portion, and the first portion of the bezel region data line comprises a curved portion.

6.-7. (canceled)

8. The display panel according to claim 1, wherein the bezel region data lines that are adjacent to each other are located in different layers.

9. The display panel according to claim 1, wherein the bezel region data lines that are adjacent to each other comprise a first bezel region data line and a second bezel region data line, the first bezel region data line is closer to the base substrate than the second bezel region data line, and a first insulation layer is arranged between the first bezel region data line and the second bezel region data line,
wherein the second bezel region data line and the display region data line connected to the second bezel region data line are connected through a via hole penetrating the first insulation layer.

10.-11. (canceled)

12. The display panel according to claim 9, further comprising an initialization signal line and a first conductive line, wherein the initialization signal line is located at a side of the plurality of gate lines away from the base substrate, the first conductive line is located in a same layer as the second bezel region data line, and the first conductive line is connected with the initialization signal line.

13. The display panel according to claim 12, wherein the first conductive line is arranged around the light transmission region,
wherein a connection position of the second bezel region data line and the display region data line connected to the second bezel region data line is located at an inner side of the first conductive line.

14. (canceled)

15. The display panel according to claim 8, further comprising a second conductive line, wherein the second conductive line is located in a same layer as the second bezel region data line, the second conductive line is arranged around the first conductive line, and the second conductive line and the first conductive line are insulated from each other.

16. (canceled)

17. The display panel according to claim 9, further comprising a plurality of light emitting control signal lines, wherein the plurality of light emitting control signal lines comprise a plurality of bezel region light emitting control signal lines located in the bezel region and a plurality of display region light emitting control signal lines located in the display region, the plurality of bezel region light emitting control signal lines are connected with the plurality of display region light emitting control signal lines, respectively, each of the plurality of bezel region light emitting control signal lines comprises a first portion, an extending direction of the first portion of the bezel region light emitting control signal line is same as the extending direction of the first portion of the bezel region data line, and the first portion of the bezel region light emitting control signal line overlaps with the first portion of one of the plurality of bezel region data lines in the direction perpendicular to the base substrate.

18. The display panel according to claim 17, wherein one of the bezel region gate line and the bezel region light emitting control signal line overlaps with the first bezel region data line, and the other of the bezel region gate line and the bezel region light emitting control signal line overlaps with the second bezel region data line.

19. The display panel according to claim 17, wherein the bezel region gate line overlaps with the first bezel region data line, the bezel region light emitting control signal line overlaps with the second bezel region data line, and a thickness of an insulation layer between the bezel region gate line and the first bezel region data line is less than a thickness of an insulation layer between the bezel region light emitting control signal line and the second bezel region data line.

20.-26. (canceled)

27. The display panel according to claim 1, further comprising an isolation pillar, wherein the isolation pillar is located in the bezel region and arranged around the light transmission region, the isolation pillar is located at a side of the plurality of bezel region data lines close to the light transmission region, and the isolation pillar forms an inner boundary of the bezel region.

28. The display panel according to claim 27, wherein the isolation pillar is made of a metal material,
wherein the isolation pillar is arranged in a same layer as the first bezel region data line or the second bezel region data line.

29. (canceled)

30. The display panel according to claim 27, wherein the isolation pillar comprises a first sub-layer, a second sub-layer and a third sub-layer, the first sub-layer is closer to the base substrate than the second sub-layer, the second sub-layer is closer to the base substrate than the third sub-layer, a size of the second sub-layer along a radial direction of the light transmission region is less than a size of the first sub-layer along the radial direction of the light transmission region, and the size of the second sub-layer along the radial direction of the light transmission region is less than a size of the third sub-layer along the radial direction of the light transmission region.

31. The display panel according to claim 30, further comprising a display unit, wherein the display unit comprises an organic light emitting diode, the organic light emitting diode comprises a light emitting functional layer, the light emitting functional layer comprises a first portion located at a side of the isolation pillar away from the light transmission region and a second portion located on the isolation pillar, and the first portion of the light emitting functional layer and the second portion of the light emitting functional layer are broken at a side edge of the isolation pillar.

32. The display panel according to claim 1, wherein the light transmission region comprises a first light transmission region and a second light transmission region, each of the plurality of bezel region gate lines comprises a second portion, the second portion of the bezel region gate line is located between the first light transmission region and the second light transmission region, the second portion of the bezel region gate line is connected with a first electrode plate of a load capacitor, and a second electrode plate of the load capacitor is opposite to the first electrode plate of the load capacitor.

33. The display panel according to claim 32, wherein the second electrode plate of the load capacitor partially overlaps with the second portion of the bezel region gate line,
wherein the display panel further comprises a first power line, wherein the first power line is configured to provide a constant voltage signal, and the second electrode plate of the load capacitor is connected with the first power line.

34.-35. (canceled)

36. A display device, comprising the display panel according to claim 1.
